(19) United States
(12) Patent Application Publication
(10) Pub. No.: US 2026/0353798 A1
(43) Pub. Date: Nov. 5, 2026

(54) SEMICONDUCTOR DEVICE

(71) Applicant: Semiconductor Energy Laboratory Co., Ltd., Atsugi-shi (JP)

(72) Inventors: Takeya HIROSE, Atsugi (JP); Kazuma FURUTANI, Atsugi (JP)

(21) Appl. No.: 19/657,107

(22) Filed: Apr. 24, 2026

(30) Foreign Application Priority Data
May 2, 2025 (JP) 2025-076827

(51) Int. Cl. H10D 86/00; G11C 5/06; G11C 7/06; H10D 30/00; H10D 30/67; H10D 62/13; H10D 62/83; H10W 20/41

(52) U.S. Cl. CPC H10D 86/201; G11C 7/06; H10D 30/6728; H10D 30/6731; H10D 30/6755; H10D 62/83; H10W 20/435; G11C 5/063; H10D 30/502; H10D 62/151

(57) ABSTRACT

A novel semiconductor device is provided. The semiconductor device includes a memory cell including a writing portion and a reading portion. The writing portion is electrically connected to a first wiring, a second wiring, and the reading portion. The reading portion is electrically connected to a third wiring, a fourth wiring, and a fifth wiring. A first signal is supplied to the first wiring. A second signal is supplied to the second wiring. In a first period, a first potential is supplied to the third wiring, the fourth wiring, and the fifth wiring. In a second period, a second potential higher than the first potential is supplied to the third wiring. A third potential lower than the first potential is supplied to the fourth wiring. The second potential or the third potential is output to the fifth wiring.

### BACKGROUND OF THE INVENTION

### 1. Field of the Invention

One embodiment of the present invention relates to a semiconductor device and a memory device.

Specific examples of the technical field of one embodiment of the present invention disclosed in this specification and the like include a large scale integration (LSI) chip, a central processing unit (CPU), a graphics processing unit (GPU), a field programmable gate array (FPGA), an application-specific integrated circuit (ASIC), an AI chip, a memory (memory device), an input device, an input/output device, a sensor, an imaging device, a display device, a light-emitting device, a power storage device, an electronic device, a driving method thereof, and a manufacturing method thereof.

Note that one embodiment of the present invention is not limited to the above technical field. One embodiment of the invention disclosed in this specification and the like relates to an object or a method. Alternatively, one embodiment of the present invention relates to a process, a machine, manufacture, or a composition of matter.

### 2. Description of the Related Art

In recent years, semiconductor devices such as LSI, CPUs, and memories (memory devices) have been developed. These semiconductor devices have been used in various electronic devices such as computers and portable information terminals. In addition, memories under development employ various storage systems for intended uses such as temporary storage at the time of executing arithmetic processing and long-term storage of data. Examples of memories with typical storage systems include a DRAM, an SRAM, and a flash memory.

A transistor using a metal oxide exhibiting semiconductor characteristics (an oxide semiconductor) as a semiconductor where a channel is formed (hereinafter also referred to as an “OS transistor”) has been known. By using an OS transistor, which has an extremely low off-state current, as a write transistor of a memory cell, a memory cell with excellent holding characteristics can be provided. For example, Non-Patent Document 1 discloses a NOSRAM (registered trademark) using an OS transistor.

### REFERENCE

### Non-Patent Document

[Non-Patent Document 1] T. Matsuzaki et al., “A 128 4bit/Cell Nonvolatile Memory with Crystalline In-Ga-Zn Oxide FET Using Vt Cancel Write Method,” ISSCC Dig. Tech. Papers, 2015, pp. 306-307.

### SUMMARY OF THE INVENTION

An object of one embodiment of the present invention is to provide a semiconductor device that can operate at high speed or a memory device including the semiconductor device. Another object of one embodiment of the present invention is to provide a semiconductor device that can reduce power consumption or a memory device including the semiconductor device. Another object of one embodiment of the present invention is to provide a semiconductor device that can increase the recording density or a memory device including the semiconductor device. Another object of one embodiment of the present invention is to provide a miniaturized semiconductor device or a memory device including the semiconductor device. Another object of one embodiment of the present invention is to provide a highly reliable semiconductor device or a memory device including the semiconductor device. Another object is to provide a novel semiconductor device or a memory device including the semiconductor device.

Note that the above objects do not preclude the existence of other objects. One embodiment of the present invention does not necessarily achieve all the above objects. Those skilled in the art can find and extract objects other than the above objects from the descriptions of the specification, the drawings, the claims, and the like.

One embodiment of the present invention is a semiconductor device including a memory cell including a writing portion and a reading portion. The writing portion is electrically connected to a first wiring, a second wiring, and the reading portion. The reading portion is electrically connected to a third wiring, a fourth wiring, and a fifth wiring. A first signal is supplied to the first wiring. A second signal is supplied to the second wiring. A first potential is supplied to the third wiring, the fourth wiring, and the fifth wiring in a first period. A second potential higher than the first potential is supplied to the third wiring, a third potential lower than the first potential is supplied to the fourth wiring, and the second potential or the third potential is output to the fifth wiring in a second period.

Another embodiment of the present invention is a semiconductor device including a memory cell including a first transistor, a second transistor, and a third transistor. A gate of the first transistor is electrically connected to a first wiring. One of a source and a drain of the first transistor is electrically connected to a second wiring. The other of the source and the drain of the first transistor is electrically connected to a gate of the second transistor and a gate of the third transistor. One of a source and a drain of the second transistor is electrically connected to a fifth wiring. The other of the source and the drain of the second transistor is electrically connected to a third wiring. One of a source and a drain of the third transistor is electrically connected to a fourth wiring. The other of the source and the drain of the third transistor is electrically connected to the fifth wiring. A first signal is supplied to the first wiring. A second signal is supplied to the second wiring. In a first period, a first potential is supplied to the third wiring, the fourth wiring, and the fifth wiring. In a second period, a second potential higher than the first potential is supplied to the third wiring, a third potential lower than the first potential is supplied to the fourth wiring, and the second potential or the third potential is output to the fifth wiring.

Alternatively, one embodiment of the present invention is a semiconductor device including a memory cell including a first transistor, a second transistor, a third transistor, and a fourth transistor. A gate of the first transistor is electrically connected to a first wiring. One of a source and a drain of the first transistor is electrically connected to a second wiring. The other of the source and the drain of the first transistor is electrically connected to a gate of the second transistor and a gate of the third transistor. One of a source and a drain of the third transistor is electrically connected to a fourth wiring. One of a source and a drain of the second transistor is electrically connected to the other of the source and the drain of the third transistor. The other of the source and the drain of the second transistor is electrically connected to a third wiring. One of a source and a drain of the fourth transistor is electrically connected to one of the source and the drain of the second transistor and the other of the source and the drain of the third transistor. The other of the source and the drain of the fourth transistor is electrically connected to a fifth wiring. A gate of the fourth transistor is electrically connected to a sixth wiring.

Alternatively, one embodiment of the present invention is a semiconductor device including a memory cell including a first transistor, a second transistor, a third transistor, and a fourth transistor. A gate of the first transistor is electrically connected to a first wiring. One of a source and a drain of the first transistor is electrically connected to a second wiring. The other of the source and the drain of the first transistor is electrically connected to a gate of the second transistor and a gate of the third transistor. One of a source and a drain of the third transistor is electrically connected to a fourth wiring. One of a source and a drain of the second transistor is electrically connected to the other of the source and the drain of the third transistor. The other of the source and the drain of the second transistor is electrically connected to a third wiring. One of a source and a drain of the fourth transistor is electrically connected to one of the source and the drain of the second transistor and the other of the source and the drain of the third transistor. The other of the source and the drain of the fourth transistor is electrically connected to a fifth wiring. A gate of the fourth transistor is electrically connected to a sixth wiring. A first signal is supplied to the first wiring. A second signal is supplied to the second wiring. In the first period, a first potential is supplied to the third wiring, the fourth wiring, and the fifth wiring. In the second period, the source and the drain of the fourth transistor is in a conduction state, a second potential higher than the first potential is supplied to the third wiring, a third potential lower than the first potential is supplied to the fourth wiring, and the second potential or the third potential is output to the fifth wiring.

In the above semiconductor device, the semiconductor device preferably includes a precharge circuit and a sense amplifier circuit. The fifth wiring is preferably electrically connected to an output terminal of the precharge circuit and a first input terminal of the sense amplifier circuit.

In the above semiconductor device, a second input terminal of the sense amplifier circuit is preferably electrically connected to the fifth wiring of an adjacent memory cell of the memory cell.

In the above semiconductor device, the channel formation region of the first transistor preferably contains indium. A channel formation region of each of the second transistor and the third transistor preferably contains silicon.

Another embodiment of the present invention is a semiconductor device including a memory cell comprising a first transistor, a second transistor, and a third transistor. The first transistor is positioned above the second transistor and the third transistor.

The first transistor includes a first semiconductor, a first insulator, a second insulator, a first conductor, a second conductor, and a third conductor. The second insulator is positioned over the second conductor. The third conductor is positioned over the second insulator. The second insulator includes an opening portion reaching the second conductor. The first semiconductor includes a region in contact with the third conductor and a region positioned in the opening portion and in contact with the second conductor. The first insulator is positioned between the first conductor and the first semiconductor.

The second transistor includes a second semiconductor, a third insulator, a fourth conductor, a fifth conductor, and a sixth conductor. The second semiconductor includes a region in contact with the fifth conductor and a region in contact with the sixth conductor. The fourth conductor is provided to surround a top surface, a bottom surface, and a pair of opposite side surfaces of the second semiconductor. The third insulator includes a region positioned between the fourth conductor and the second semiconductor.

The third transistor includes a third semiconductor, a fourth insulator, a seventh conductor, an eighth conductor, and a ninth conductor. The third semiconductor includes a region in contact with the eighth conductor and a region in contact with the ninth conductor. The seventh conductor is provided to surround a top surface, a bottom surface, and a pair of opposite side surfaces of the third semiconductor. The fourth insulator includes a region positioned between the seventh conductor and the third semiconductor.

The first semiconductor contains indium. The second semiconductor and the third semiconductor contain silicon or silicon germanium. The second conductor is electrically connected to the fourth conductor and the seventh conductor. The sixth conductor is electrically connected to the ninth conductor.

In the above semiconductor device, the fifth conductor, the sixth conductor, the eighth conductor, and the ninth conductor are preferably silicide.

The above semiconductor device preferably further includes a region where the second semiconductor and the third semiconductor overlap with each other in a plan view.

In the above semiconductor device, the first semiconductor preferably includes a region in contact with a side surface of the second insulator in the opening portion. The first insulator and the first conductor preferably include a region positioned in the opening portion.

In the above semiconductor device, the first conductor preferably includes a region in contact with a top surface of the second insulator and positioned over the second conductor and under the third conductor. The first insulator preferably includes a region in contact with a side surface of the second insulator in the opening portion.

One embodiment of the present invention can provide a semiconductor device that can operate at high speed or a memory device including the semiconductor device. Another embodiment of the present invention can provide a semiconductor device that can reduce power consumption or a memory device including the semiconductor device. Another embodiment of the present invention can provide a semiconductor device that can increase the recording density or a memory device including the semiconductor device. Another embodiment of the present invention can provide a miniaturized semiconductor device or a memory device including the semiconductor device. Another embodiment of the present invention can provide a highly reliable semiconductor device or a memory device including the semiconductor device. A novel semiconductor device or a memory device including the semiconductor device can also be provided.

Note that the above effects do not preclude the existence of other effects. One embodiment of the present invention does not necessarily achieve all the above effects. Those skilled in the art can find and extract effects other than the above effects from the descriptions of the specification, the drawings, the claims, and the like.

### BRIEF DESCRIPTION OF THE DRAWINGS

FIGS. 1A and 1B are diagrams illustrating a circuit structure example of a semiconductor device.

FIGS. 2A to 2E are diagrams illustrating circuit structure examples of the semiconductor device.

FIGS. 3A and 3B are diagrams illustrating circuit structure examples of the semiconductor device.

FIG. 4 is a timing chart illustrating an operation example of the semiconductor device.

FIG. 5 is a timing chart illustrating an operation example of the semiconductor device.

FIG. 6 is a circuit diagram illustrating an operation example of the semiconductor device.

FIG. 7 is a circuit diagram illustrating an operation example of the semiconductor device.

FIG. 8 is a circuit diagram illustrating an operation example of the semiconductor device.

FIG. 9 is a circuit diagram illustrating an operation example of the semiconductor device.

FIG. 10 is a circuit diagram illustrating an operation example of the semiconductor device.

FIG. 11 is a circuit diagram illustrating an operation example of the semiconductor device.

FIG. 12 is a circuit diagram illustrating an operation example of the semiconductor device.

FIG. 13 is a circuit diagram illustrating an operation example of the semiconductor device.

FIG. 14 is a circuit diagram illustrating an operation example of the semiconductor device.

FIG. 15 is a circuit diagram illustrating a structure example of the semiconductor device.

FIGS. 16A1, 16A2, 16B, and 16C are diagrams illustrating structure examples of the semiconductor device.

FIGS. 17A to 17C are diagrams illustrating a structure example of the semiconductor device.

FIG. 18 is a diagram illustrating the structure example of the semiconductor device.

FIG. 19 is a diagram illustrating the structure example of the semiconductor device.

FIG. 20 is a diagram illustrating the structure example of the semiconductor device.

FIG. 21 is a diagram illustrating the structure example of the semiconductor device.

FIG. 22 is a diagram illustrating the structure example of the semiconductor device.

FIG. 23 is a diagram illustrating the structure example of the semiconductor device.

FIGS. 24A to 24C are diagrams illustrating a structure example of the semiconductor device.

FIGS. 25A and 25B are diagrams illustrating the structure example of the semiconductor device.

FIG. 26 is a diagram illustrating a structure example of the semiconductor device.

FIG. 27 is a diagram illustrating a structure example of the semiconductor device.

FIG. 28 is a block diagram illustrating a structure example of a semiconductor device.

FIGS. 29A to 29C are perspective views of a semiconductor device.

FIGS. 30A and 30B are diagrams of examples of electronic components.

FIGS. 31A to 31C are diagrams of an example of a large computer. FIG. 31D is a diagram of an example of space equipment. FIG. 31E is a diagram of an example of a storage system applicable in a data center.

FIG. 32A1 to 32A7 and FIGS. 32B1 to 32B6 are diagrams each illustrating electrical connection.

### DETAILED DESCRIPTION OF THE INVENTION

Embodiments will be described with reference to the drawings. Note that the present invention is not limited to the following description and it will be easily understood by those skilled in the art that modes and details can be modified in various ways without departing from the spirit and the scope of the present invention. Thus, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases. Moreover, some components may be omitted in a perspective view, a plan view, or the like for easy understanding of the drawings.

The position, size, thickness, range, and the like of each component in drawings are exaggerated for clarity in some cases. Therefore, the disclosed invention is not necessarily limited to the position, size, thickness, range, or the like of each component disclosed in the drawings.

In the drawings for this specification and the like, arrows indicating an X direction, a Y direction, and a Z direction are shown in some cases. In this specification and the like, the “X direction” is a direction along the X axis, and unless otherwise specified, the forward direction and the reverse direction are not distinguished in some cases. The same applies to the “Y direction” and the “Z direction”.

Note that ordinal numbers such as “first” and “second” in this specification and the like are used for convenience and do not limit the number or the order (e.g., the order of steps or the stacking order) of components. The ordinal number added to a component in a part of this specification may be different from the ordinal number added to the component in another part of this specification or the scope of claims.

In this specification, drawings, and the like, when a plurality of components are denoted by the same reference numeral, and, particularly when they need to be distinguished from each other, identification signs such as “A”, “b”, “_1”, “[n]”, or “[m, n]” are sometimes added to the reference numeral, for example. When matters common to a plurality of components with identification signs are described or when they do not need to be distinguished from each other, no identification sign is added in some cases.

In this specification, a plan view means a view to observe the component from a normal direction of a surface where the component is formed or from a normal direction of a surface of a support (e.g., a substrate) where the component is formed.

Note that the expressions indicating directions such as “over” and “under” are basically used to correspond to the directions of drawings. However, in some cases, the term “over” or “under” in the specification indicates a direction that does not correspond to the apparent direction in the drawings, for the purpose of easy description or the like. For example, in the description of the stacked order (or the formation order) of a stacked body or the like, even in the case where a surface on which the stacked body is provided (e.g., a formation surface, a support surface, a bonding surface, or a planar surface) is positioned above the stacked body in the drawings, the formation surface side and the opposite direction are expressed using “under” and “over”, respectively, in some cases.

In this specification and the like, the term “parallel” indicates that the angle subtended between two straight lines is greater than or equal to −10° and less than or equal to 10°. Thus, the case where the angle is greater than or equal to −5° and less than or equal to 5° is also included. The term “substantially parallel” indicates that the angle formed between two straight lines is greater than or equal to −20° and less than or equal to 20°. The term “perpendicular” indicates that the angle subtended between two straight lines is greater than or equal to 80° and less than or equal to 100°. Thus, the case where the angle is greater than or equal to 85° and less than or equal to 95° is also included. In addition, the term “substantially perpendicular” indicates that the angle formed between two straight lines is greater than or equal to 70° and less than or equal to 110°.

Note that in this specification and the like, the expression “substantially level with” indicates a structure having the same level from a reference surface (e.g., a flat surface such as a substrate surface) in a cross-sectional view. For example, in a manufacturing process, planarization treatment (typically, CMP treatment) is performed, whereby the surface(s) of a single layer or a plurality of layers are exposed in some cases. In this case, the surfaces on which the CMP treatment is performed are at the same level from a reference surface. Note that the plurality of layers may be at different levels depending on a treatment apparatus, a treatment method, materials of a surface performed treatment, polishing rate, or etching rate of the CMP treatment. This case is also regarded as being “level with” in this specification and the like.

In this specification and the like, the expression “an end portion is aligned with another end portion” means that at least outlines of stacked layers partly overlap with each other in a plan view. For example, the case of patterning an upper layer and a lower layer with the use of the same mask pattern or mask patterns that are partly the same is included.

In this specification and the like, a space group is represented using the short symbol of the international notation (or the Hermann-Mauguin notation). In addition, the Miller index is used for the expression of crystal planes and crystal orientations. In the crystallography, a bar is placed over a number in the expression of space groups, crystal planes, and crystal orientations; in this specification and the like, because of format limitations, space groups, crystal planes, and crystal orientations are sometimes expressed by placing a minus sign (−) in front of a number instead of placing a bar over the number. Furthermore, an individual orientation that shows an orientation in crystal is expressed with “[ ]”, a set orientation that shows all of the equivalent orientations is expressed with “< >”, an individual plane that shows a crystal plane is expressed with “( )”, and a set plane having equivalent symmetry is expressed with “{ }”.

In this specification and the like, the term “film” and the term “layer” can be interchanged with each other. For example, in some cases, the term “insulating layer” can be interchanged with the term “insulating film”.

Note that in this specification and the like, an oxynitride refers to a material in which the oxygen atom content is higher than the nitrogen atom content, and a nitride oxide refers to a material in which the nitrogen atom content is higher than the oxygen atom content. For example, silicon oxynitride refers to a material that contains more oxygen atoms than nitrogen atoms, and silicon nitride oxide refers to a material that contains more nitrogen atoms than oxygen atoms.

Note that in this specification and the like, a semiconductor device refers to a device that utilizes semiconductor characteristics, and means a transistor, a circuit including a transistor, a device including the circuit, and the like. The semiconductor device also means devices that can function by utilizing semiconductor characteristics. For example, an integrated circuit, a chip including an integrated circuit, and an electronic component including a chip in a package are examples of the semiconductor device. In some cases, a memory device, a display device, a light-emitting device, a lighting device, an electronic device, and the like themselves are semiconductor devices and also include a semiconductor device.

A transistor is a kind of semiconductor device and enables amplification of a current or a voltage, a switching operation for controlling conduction or non-conduction, and the like. A transistor in this specification includes, in its category, an insulated-gate field-effect transistor (IGFET) and a thin film transistor (TFT).

In this specification and the like, a transistor including a metal oxide exhibiting a semiconductor characteristics (an oxide semiconductor) in its semiconductor layer and a transistor including a metal oxide exhibiting a semiconductor characteristics (an oxide semiconductor) in its channel formation region are each sometimes referred to as an OS transistor. A transistor including silicon in its channel formation region is sometimes referred to as a Si transistor.

In this specification and the like, a transistor is an element including at least three terminals of a gate, a drain, and a source. The transistor includes a region where a channel is formed (also referred to as a channel formation region) between the drain (a drain terminal, a drain region, or a drain electrode) and the source (a source terminal, a source region, or a source electrode), and current can flow between the source and the drain through the channel formation region.

The functions of a “source” and a “drain” are sometimes replaced with each other when a transistor of different polarity is used or when the direction of current flow is changed in a circuit operation, for example. Thus, the terms “source” and “drain” can be used interchangeably in this specification.

In addition to the above three terminals, the transistor may include a back gate. In this case, in this specification and the like, one of the gate and the back gate of the transistor may be referred to as a first gate and the other of the gate and the back gate of the transistor may be referred to as a second gate. In some cases, the terms “gate” and “back gate” can be replaced with each other in one transistor.

In this specification and the like, a “conduction state” or an “on state” of a transistor refers to a state where a source and a drain of the transistor can be regarded as being electrically short-circuited, a state where current can be made to flow between the source and the drain, or the like. The “conduction state” or the “on state” may refer to the state of an n-channel transistor where the voltage between its gate and source is higher than the threshold voltage or the state of a p-channel transistor where the voltage between its gate and source is lower than the threshold voltage, for example. Furthermore, a “non-conduction state”, a “cutoff state”, or an “off state” of a transistor refers to a state where a source and a drain of the transistor can be regarded as being electrically disconnected. For example, the “non-conduction state”, the “cutoff state”, or the “off state” may refer to the state of an n-channel transistor where the voltage between its gate and source is lower than the threshold voltage or the state of a p-channel transistor where the voltage between its gate and source is higher than the threshold voltage.

In this specification and the like, “gate voltage” refers to the voltage between a gate and a source, “drain voltage” refers to the voltage between a drain and a source, and “back gate voltage” refers to the voltage between a back gate and a source in some cases. In addition, a “drain current” refers to a current flowing between the drain and the source in some cases. The expressions “high gate voltage”, “high drain voltage”, “high back gate voltage”, and the like for an n-channel transistor can be replaced with the expressions “low gate voltage”, “low drain voltage”, “low back gate voltage”, and the like for a p-channel transistor, respectively, as appropriate. The expressions “low gate voltage”, “low drain voltage”, “low back gate voltage”, and the like for an n-channel transistor can be replaced with the expressions “high gate voltage”, “high drain voltage”, “high back gate voltage”, and the like for a p-channel transistor, respectively, as appropriate.

In this specification and the like, an “off-state current” of a transistor refers to a drain current of the transistor in the off state unless otherwise specified. Note that an off-state current and a current that flows between a gate and a source or a drain (also referred to as a gate leakage current) are each referred to as leakage current in some times in this specification and the like.

In this specification and the like, the terms “electrode”, “wiring”, “terminal”, and the like do not limit the functions of components. For example, an “electrode” is used as part of a “wiring” in some cases, and vice versa. Furthermore, for example, the term “electrode” or “wiring” can also mean a combination of a plurality of “electrodes” or “wirings” provided in an integrated manner. For another example, a “terminal” is used as part of a “wiring” or an “electrode” in some cases, and vice versa. Furthermore, the term “terminal” includes the case where a plurality of “electrodes”, “wirings”, “terminals”, or the like are formed in an integrated manner. Therefore, for example, an “electrode” can be part of a “wiring” or a “terminal”, and a “terminal” can be part of a “wiring” or an “electrode”. Moreover, the terms “electrode”, “wiring”, and “terminal” are sometimes replaced with the term “region” and “conductive layer”, for example.

In this specification and the like, the terms “wiring”, “signal line”, “power supply line”, and the like can be interchanged with each other depending on the case or in accordance with circumstances. For example, the term “wiring” can be changed into the term “signal line” in some cases. For another example, the term “wiring” can be changed into the term such as “power supply line” in some cases. Conversely, the term such as “signal line” or “power supply line” can be changed into the term “wiring” in some cases. The term “power supply line” or the like can be changed into the term “signal line” or the like in some cases. Conversely, the term “signal line” or the like can be changed into the term “power supply line” or the like in some cases. The term “potential” that is applied to a wiring can be changed into the term “signal” or the like depending on the case or in accordance with circumstances. Conversely, the term “signal” or the like can be changed into the term “potential” in some cases.

In this specification, a “source” refers to a source region, a source electrode, or a source wiring. A source region refers to one of two regions adjacent to a channel formation region in a semiconductor layer. A source electrode refers to a conductive layer including part connected to a source region.

In this specification, a “drain” refers to a drain region, a drain electrode, or a drain wiring. A drain region refers to the other of the two regions adjacent to the channel formation region in the semiconductor layer. A drain electrode refers to a conductive layer including part connected to a drain region.

In this specification, a “gate” refers to a gate electrode or a gate wiring. A gate electrode refers to an electrode that overlaps with a semiconductor layer of a transistor and has a function of controlling the resistance between a source and a drain of the transistor with use of a supplied voltage.

In this specification, in some cases, one of a source and a drain of a transistor is referred to as a “first terminal of a transistor” and the other of the source and the drain of the transistor is referred to as a “second terminal of a transistor”.

Voltage refers to a difference between a given potential and a reference potential (e.g., a ground potential or a source potential) in many cases. Therefore, the terms “voltage” and “potential” can be replaced with each other in many cases. In this specification and the like, “voltage” and “potential” can be replaced with each other unless otherwise specified.

In this specification and the like, a high power supply potential VDD (hereinafter also simply referred to as “VDD”) is a power supply potential higher than a low power supply potential VSS. The low power supply potential VSS (hereinafter also simply referred to as “VSS”) is a power supply potential lower than the high power supply potential VDD. In addition, a ground potential GND (hereinafter, also simply referred to as “GND”) can be used as VDD or VSS. For example, VSS is a potential lower than GND when VDD is GND, and VDD is a potential higher than GND when VSS is GND.

In this specification and the like, a potential H is a potential with which an n-channel field-effect transistor (also referred to as an “n-type transistor”) is turned on and also a potential with which a p-channel field-effect transistor (also referred to as a “p-type transistor”) is turned off. A potential L is a potential with which an n-type transistor is turned off and a p-type transistor is turned on. Thus, the potential H is higher than the potential L. The potential H is sometimes equal to VDD. The potential L is sometimes equal to VSS. Unless otherwise specified, transistors described in this specification are enhancement (normally-off) n-type transistors.

In the drawings and the like, for easy understanding of the potentials of a wiring, an electrode, and the like, “H” representing the potential H or “L” representing the potential L is sometimes written near the wiring, the electrode, and the like. In addition, enclosed “H” or “L” is sometimes written near a wiring, an electrode, and the like whose potentials are changed. Moreover, a symbol “×” is sometimes written on a transistor in an off state. Furthermore, arrows indicating the direction of current flowing are shown in some cases.

The expression “connection” in this specification includes “electrical connection”, for example. When the expression “electrical connection” is used to specify the connection relation of a circuit element as an object, “electrical connection” includes “direct connection” and “indirect connection”, for example. The expression “A and B are directly connected” means that A and B are connected to each other without a circuit element (e.g., a transistor or a switch; a wiring is not a circuit element) therebetween, for example. Meanwhile, the expression “A and B are indirectly connected” means that A and B are connected to each other with at least one circuit element therebetween, for example. Note that A, B, and later-described C each denote an object such as an element, a circuit, a wiring, an electrode, a terminal, a semiconductor layer, or a conductive layer.

Here, in the case where a connection relation is specified as “A and B are indirectly connected”, the following connection relations are included, for example. That is, on the assumption that a circuit is in operation, the circuit can be specified as “A and B are indirectly connected” as an object when electric signal transmission and reception, potential interaction, or the like between A and B occurs at some point during the operation period of the circuit. Note that even when neither electric signal transmission and reception nor potential interaction between A and B occurs at some point during the operation of the circuit, the circuit can be specified as “A and B are indirectly connected” as long as electric signal transmission and reception or potential interaction between A and B occurs at another point during the operation period of the circuit. Note that the expression “A and B are indirectly connected” specifies the connection relation of a circuit element as an object. Thus, even when a circuit is not supplied with a power supply voltage and is not in operation, for example, the circuit can be specified as “A and B are indirectly connected” as an object (note that this specification is limited to, for example, the case where electric signal transmission and reception, potential interaction, or the like between A and B occurs during the operation period of the circuit when the circuit is supplied with a power supply voltage to be in operation).

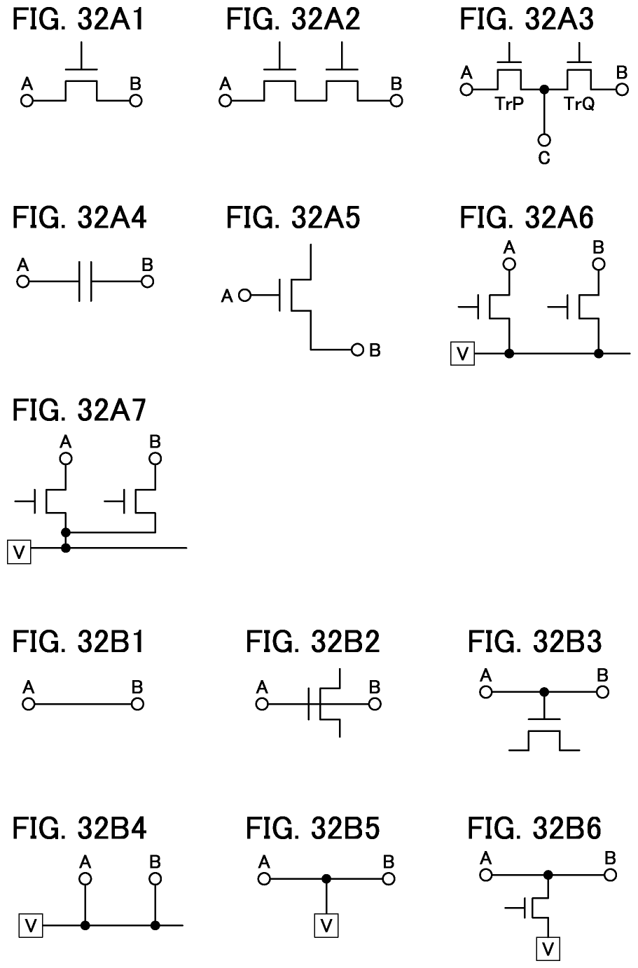

Specific examples of the case of “indirect connection” are described below. First, examples of the case where the expression “A and B are indirectly connected” can be used include the case where A and B are connected to each other through a source and a drain of at least one transistor as in FIGS. 32A1 and 32A2. Another example thereof is the case where A and B are connected to each other with at least one switch therebetween. In the case where the expression “A and B are indirectly connected” can be used, one transistor between A and B is brought into an on state, a conduction state, or a state where a current can flow at least once on the assumption that a circuit is in operation. The case where the expression “A and B are indirectly connected” can be used may include a period in which the one transistor between A and B is brought into an off state or a non-conduction state. In the case where the expression “A and B are indirectly connected” can be used, each of a plurality of transistors between A and B is brought into an on state, a conduction state, or a state where a current can flow at least once when the plurality of transistors are connected between A and B on the assumption that a circuit is in operation. That is, in the case where the expression “A and B are indirectly connected” can be used, it is not necessary that all of the plurality of transistors be brought into an on state, a conduction state, or a state where a current can flow at the same time. Accordingly, in the case where the expression “A and B are indirectly connected” can be used, the plurality of transistors between A and B may be brought into an off state or a non-conduction state at the same time or at different times. For another example, when A and C are connected to each other through a source and a drain of a transistor TrP and B and C are connected to each other through a source and a drain of a transistor TrQ as shown in FIG. 32A3, it can be specified as “A and C are indirectly connected”, “B and C are indirectly connected”, or “A and B are indirectly connected”. Note that in the case where a constant potential V is supplied to C from a power source, GND, or the like as described later, the expression “A and C are indirectly connected” or “B and C are indirectly connected” can be used; however, the expression “A and B are indirectly connected” cannot be used.

The examples of the cases where the expression “indirect connection” can be used and cannot be used are described above, and another example of the case where the expression “indirect connection” cannot be used is described below. Even when electric signal transmission and reception, potential interaction, or the like between A and B occurs during the operation period of the circuit, the expression “A and B are indirectly connected” cannot be used in some cases exceptionally. Examples of the exceptional case include the case where A and B are connected to each other with an insulator therebetween. That is, in the case where A and B are connected to each other with an insulator therebetween, the expression “A and B are indirectly connected” cannot be used. A specific example of the case where A and B are connected to each other with an insulator therebetween is the case where a capacitor is connected between A and B as in FIG. 32A4. Another example thereof is the case where there is a gate insulating film of a transistor or the like between A and B as in FIG. 32A5. In this case, the expression “A (a gate of the transistor) and B (a source or a drain of the transistor) are indirectly connected” cannot be used.

Another example of the case where the expression “A and B are indirectly connected” cannot be used is the case where neither electric signal transmission and reception nor potential interaction between A and B occurs. For example, a plurality of transistors are connected through their sources and drains on the path from A to B and a constant potential V is supplied from a power source, GND, or the like to a node between one of the transistors and another one of the transistors as in FIGS. 32A6 and 32A7. In this case, the expression “A and B are indirectly connected” cannot be used; however, the expression “A and V are indirectly connected” or “B and V are indirectly connected” can be used. Note that in FIG. 32A3, when A and C are connected to each other through the source and the drain of the transistor TrP, B and C are connected to each other through the source and the drain of the transistor TrQ, and the constant potential V is supplied from a power source, GND, or the like to C, the same connection relation as that in FIGS. 32A6 and 32A7 is established; thus, the expression “A and B are indirectly connected” cannot be used; however, the expression “A and C are indirectly connected” or “B and C are indirectly connected” can be used.

The examples of “indirect connection” are described above. The specification of “indirect connection” is included in the specification of “electrical connection”, for example; thus, in the case where the expression “A and B are indirectly connected” is used, the expression “A and B are electrically connected” can also be used.

Next, specific examples of the case of “direct connection” are described. Examples of the case where the expression “A and B are directly connected” can be used include the case where A and B are connected to each other without a circuit element therebetween as in FIGS. 32B1, 32B2, and 32B3. When A and B are connected to a power source, GND, or the like from which the constant potential V is supplied without a circuit element therebetween as in FIGS. 32B4 and 32B5, the expression “A and B are directly connected”, “A and V are directly connected”, or “B and V are directly connected” can be used. Note that when A (or B) is connected to the constant potential V through a source and a drain of a transistor as in FIG. 32B6, the expression “A and B are directly connected” can also be used. Note that A and V or B and V are connected to each other through the source and the drain of the transistor, and thus, they cannot be regarded as being in direct connection, and the expression “A and V are indirectly connected” or “B and V are indirectly connected” can be used.

The examples of “direct connection” are described above. The specification of “direct connection” is included in the specification of “electrical connection”, for example; thus, in the case where the expression “A and B are directly connected” is used, the expression “A and B are electrically connected” can also be used.

### Embodiment 1

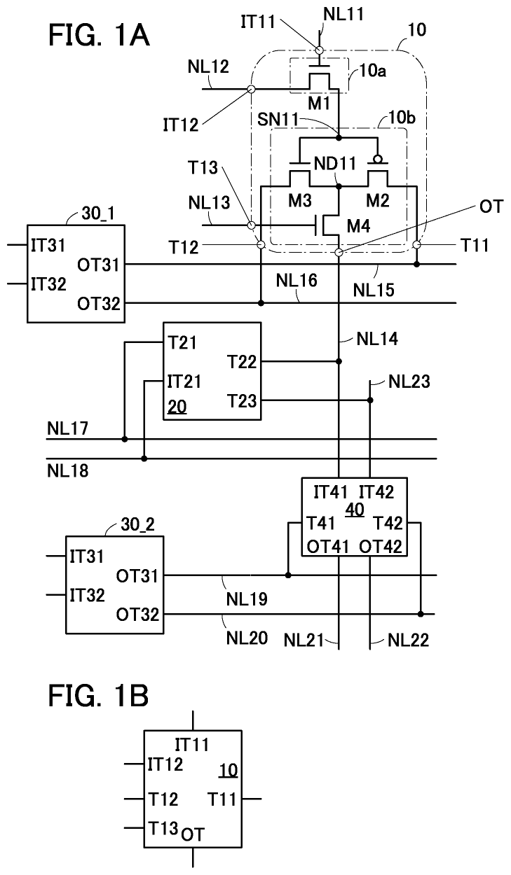

A semiconductor device of one embodiment of the present invention will be described with reference to drawings. FIG. 1A is a circuit diagram of a semiconductor device of one embodiment of the present invention. FIG. 1B shows a memory cell 10.

### Example of Circuit Structure

The semiconductor device in FIG. 1A includes the memory cell 10. The semiconductor device in FIG. 1A can further include a circuit 20, a circuit 30_1, a circuit 30_2, and a circuit 40. The circuit 20 can function as a precharge circuit. The circuit 30_1 has a function of supplying a signal for driving a reading portion 10b of the memory cell 10. The circuit 30_2 has a function of supplying a signal for driving the circuit 40. The circuit 40 can function as a sense amplifier circuit.

The memory cell 10 includes a writing portion 10a and the reading portion 10b. The writing portion 10a is connected to a wiring NL11, a wiring NL12, and the reading portion 10b. The reading portion 10b is connected to a wiring NL13, a wiring NL14, a wiring NL15, a wiring NL16, and the writing portion 10a.

FIG. 1B shows the memory cell 10 shown in FIG. 1A. As shown in FIG. 1B, the memory cell 10 includes a terminal IT11, a terminal IT12, a terminal T11, a terminal T12, a terminal T13, and a terminal OT.

The memory cell 10 includes a transistor M1, a transistor M2, a transistor M3, and a transistor M4 as shown in FIG. 1A. Specifically, the writing portion 10a of the memory cell 10 includes the transistor M1, and the reading portion 10b of the memory cell 10 includes the transistors M2, M3, and M4.

A gate of the transistor M1 is connected to the wiring NL11. One of a source and a drain of the transistor M1 is connected to the wiring NL12. The other of the source and the drain of the transistor M1 is connected to a gate of the transistor M2 and a gate of the transistor M3. One of a source and a drain of the transistor M3 is connected to the wiring NL16. One of a source and a drain of the transistor M2 is connected to the other of the source and the drain of the transistor M3. The other of the source and the drain of the transistor M2 is connected to the wiring NL15. One of a source and a drain of the transistor M4 is connected to the one of the source and the drain of the transistor M2 and the other of the source and the drain of the transistor M3. The other of the source and the drain of the transistor M4 is connected to the wiring NL14.

A node SN11 refers to a region where the other of the source and the drain of the transistor M1, the gate of the transistor M2, and the gate of the transistor M3 are connected to each other and always have the same potential. A node ND11 refers to a region where the one of the source and the drain of the transistor M4, the one of the source and the drain of the transistor M2, and the other of the source and the drain of the transistor M3 are connected to each other and always have the same potential.

As shown in FIG. 1A, the wiring NL15 is connected to a terminal OT31 of the circuit 30_1. The wiring NL16 is connected to a terminal OT32 of the circuit 30_1.

The wiring NL14 is connected to a terminal T22 of the circuit 20 and a terminal IT41 of the circuit 40. A wiring NL23 is connected to a terminal T23 of the circuit 20 and a terminal IT42 of the circuit 40. The wiring NL23 corresponds to the wiring NL14 of an adjacent memory cell. A wiring NL17 is connected to a terminal T21 of the circuit 20. A wiring NL18 is connected to a terminal IT21 of the circuit 20.

A wiring NL19 is connected to the terminal OT31 of the circuit 30_2 and a terminal T41 of the circuit 40. A wiring NL20 is connected to the terminal OT32 of the circuit 30_2 and a terminal T42 of the circuit 40.

A wiring NL21 is connected to a terminal OT41 of the circuit 40. A wiring NL22 is connected to a terminal OT42 of the circuit 40.

Although the transistor M1, the transistor M3, and the transistor M4 are n-type transistors and the transistor M2 is a p-type transistor in the memory cell 10 in FIG. 1A, one embodiment of the present invention is not limited thereto. For example, the transistor M4 can be a p-type transistor.

A transistor having a back gate can be used as any of the transistors included in the memory cell 10.

The transistor M1 in the memory cell 10 functions as a holding transistor that holds data (here, charge corresponding to a certain potential) written to the node SN11. Thus, an OS transistor is preferably used as the transistor M1. An OS transistor uses an oxide semiconductor having a band gap of 2 eV or more as a semiconductor layer where a channel of an OS transistor is formed, and thus has an significantly low off-state current as compared with a transistor using silicon in a semiconductor layer where a channel is formed (also referred to as a “Si transistor”). Specifically, the off-state current per micrometer of channel width of an OS transistor can be lower than or equal to 1 pA (1×10⁻¹² A), lower than or equal to 1 aA (1×10⁻¹⁸ A), lower than or equal to 1 zA (1×10⁻²¹ A), or lower than or equal to 1 yA (1×10⁻²⁴ A) in a room-temperature environment.

In addition, the OS transistor operates stably in a high-temperature environment and has small fluctuation in characteristics. For example, the off-state current hardly increases even at an environment temperature higher than or equal to 100 ° C and lower than or equal to 200 ° C. Furthermore, the on-state current is less likely to decrease even at an environment temperature higher than or equal to 100 ° C and lower than or equal to 200 ° C. A semiconductor device including the OS transistor can operate stably and have high reliability even in a high-temperature environment.

Furthermore, the OS transistor allows a variation in electrical characteristics due to irradiation with radiation such as cosmic rays to be small. That is, a soft error due to radiation is less likely to occur, and thus, the semiconductor device including the OS transistor has high reliability.

When an OS transistor is used as the transistor M1 in this manner, the amount of charge held at the node SN11 is not easily reduced, so that a change in the potential of the node SN11 can be inhibited. Thus, data written to the node SN11 can be held for a long period.

The transistor M2, the transistor M3, and the transistor M4 in the memory cell 10 used in the semiconductor device of one embodiment of the present invention can each function as a transistor for reading data held in the node SN11. Therefore, a transistor having a higher field-effect mobility or a higher on-state current than the transistor M1 is preferably used. For example, a Si transistor can be used. Since the Si transistor has higher mobility than the OS transistor, data held in the memory cell 10 can be read at a higher speed. For example, the Si transistor is preferably a transistor including a sheet-like channel, in which a gate electrode surrounds a top surface, a bottom surface, and a pair of opposite side surfaces of a region where the sheet-like channel is formed and a gate insulating film is provided between the gate electrode and the channel formation region. This enables a gate electric field to be efficiently applied to the channel formation region, so that the on/off controllability of the transistor can be improved; for example, an increase in on-state current and a reduction in off-state current can be achieved.

For example, when an OS transistor is used as the transistor M1 and a Si transistor is used as each of the transistor M2, the transistor M3, and the transistor M4, a highly reliable memory cell capable of high-speed operation can be achieved.

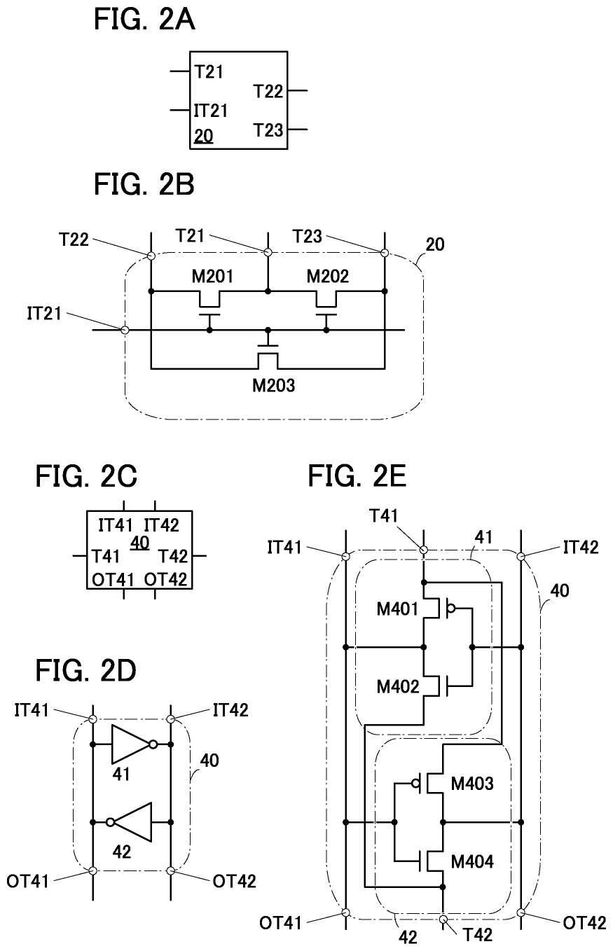

The circuit 20 is an equalizer circuit and can function as a precharge circuit. FIG. 2A shows the circuit 20. FIG. 2B shows an example of a circuit diagram of the circuit 20.

As shown in FIG. 2A, the circuit 20 includes at least the terminal IT21, the terminal T21, the terminal T22, and the terminal T23.

An example of the circuit 20 in FIG. 2B includes a transistor M201, a transistor M202, and a transistor M203. A gate of the transistor M201, a gate of the transistor M202, and a gate of the transistor M203 are connected to the terminal IT21. One of a source and a drain of the transistor M201 and one of a source and a drain of the transistor M203 are connected to the terminal T22. The other of the source and the drain of the transistor M201 and one of a source and a drain of the transistor M202 are connected to the terminal T21. The other of the source and the drain of the transistor M202 and the other of the source and the drain of the transistor M203 are connected to the terminal T23.

In the circuit 20, when the transistors M201, M202, and M203 are turned on in response to a signal input from the terminal IT21, the terminals T21, T22, and T23 are connected to each other and have the same potential. For example, in a state where a potential Vpre is supplied to the terminal T21, when the transistors M201, M202, and M203 are turned on in response to the signal input from the terminal IT21, the potential Vpre is supplied to the terminal T22 and the terminal T23.

Although the transistors M201, M202, and M203 included in the circuit 20 are n-type transistors in FIG. 2B, one embodiment of the present invention is not limited thereto. For example, p-type transistors may be used as these transistors.

The circuit 40 can function as a sense amplifier circuit. FIG. 2C shows the circuit 40. FIG. 2D show an example of a logic circuit diagram of the circuit 40. FIG. 2E shows an example of a circuit diagram of the circuit 40.

As shown in FIG. 2C, the circuit 40 includes at least the terminal IT41, the terminal IT42, the terminal T41, the terminal T42, the terminal OT41, and the terminal OT42.

The example of the logic circuit diagram of the circuit 40 in FIG. 2D includes an inverter 41 and an inverter 42.

The example of the circuit diagram of the circuit 40 in FIG. 2E includes a transistor M401, a transistor M402, a transistor M403, and a transistor M404. Note that the inverter 41 includes the transistor M401 and the transistor M402. The inverter 42 includes the transistor M403 and the transistor M404. A gate of the transistor M401 is connected to a gate of the transistor M402. The terminal T41 is connected to one of a source and a drain of the transistor M401. The other of the source and the drain of the transistor M401 is connected to one of a source and a drain of the transistor M402. The other of the source and the drain of the transistor M402 is connected to the terminal T42. A gate of the transistor M403 is connected to a gate of the transistor M404. The terminal T41 is connected to one of a source and a drain of the transistor M403. The other of the source and the drain of the transistor M403 is connected to one of a source and a drain of the transistor M404. The other of the source and the drain of the transistor M404 is connected to the terminal T42. The terminal IT41 is connected to the other of the source and the drain of the transistor M401, the one of the source and the drain of the transistor M402, the gate of the transistor M403, the gate of the transistor M404, and the terminal OT41. The terminal IT42 is connected to the gate of the transistor M401, the gate of the transistor M402, the other of the source and the drain of the transistor M403, the one of the source and the drain of the transistor M404, and the terminal OT42.

The circuit 40 has a function of amplifying a potential difference between a potential of a signal input to the terminal IT41 and a potential of a signal input to the terminal IT42. Specifically, the case is considered where a high power supply potential VDD, a low power supply potential VSS, and a power supply voltage are supplied to the terminal T41, the terminal T42, and the inverters 41 and 42, respectively, and there is a potential difference between a signal input to the terminal IT41 and a signal input to the terminal IT42. When the potential of the signal input to the terminal IT41 is lower than the potential of the signal input to the terminal IT42, the potential of the terminal IT41 (the terminal OT41) becomes VSS and the potential of the terminal IT42 (the terminal OT42) becomes VDD. In contrast, when the potential of the signal input to the terminal IT41 is higher than the potential of the signal input to the terminal IT42, the potential of the terminal IT41 (the terminal OT41) becomes VDD and the potential of the terminal IT42 (the terminal OT42) becomes VSS.

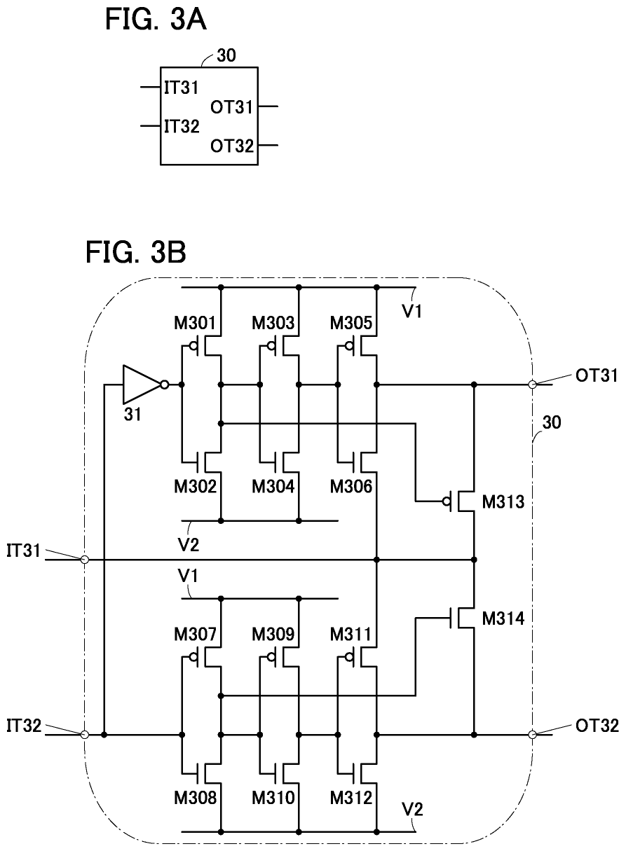

A circuit 30 that can be used as each of the circuit 30_1 and the circuit 30_2 is described. The circuit 30 can function as a sense amplifier driver circuit. FIG. 3A shows the circuit 30. FIG. 3B shows an example of a circuit diagram of the circuit 30.

As shown in FIG. 3A, the circuit 30 includes at least a terminal IT31, a terminal IT32, the terminal OT31, and the terminal OT32.

An example of the circuit 30 in FIG. 3B includes a transistor M301, a transistor M302, a transistor M303, a transistor M304, a transistor M305, a transistor M306, a transistor M307, a transistor M308, a transistor M309, a transistor M310, a transistor M311, a transistor M312, a transistor M313, a transistor M314, and an inverter 31.

The terminal IT32 is connected to an input terminal of the inverter 31, a gate of the transistor M307, and a gate of the transistor M308. An output terminal of the inverter 31 is connected to a gate of the transistor M301 and a gate of the transistor M302. One of a source and a drain of the transistor M301 is connected to a terminal V1. The other of the source and the drain of the transistor M301 is connected to one of a source and a drain of the transistor M302, a gate of the transistor M303, a gate of the transistor M304, and a gate of the transistor M313. The other of the source and the drain of the transistor M302 is connected to a terminal V2. One of a source and a drain of the transistor M303 is connected to the terminal V1. The other of the source and the drain of the transistor M303 is connected to one of a source and a drain of the transistor M304, a gate of the transistor M305, and a gate of the transistor M306. The other of the source and the drain of the transistor M304 is connected to the terminal V2. One of a source and a drain of the transistor M305 is connected to the terminal V1. The other of the source and the drain of the transistor M305 is connected to one of a source and a drain of the transistor M306, the terminal OT31, and one of a source and a drain of the transistor M313. The other of the source and the drain of the transistor M306 is connected to the terminal IT31. The other of the source and the drain of the transistor M313 is electrically connected to the terminal IT31 and one of a source and a drain of the transistor M314.

One of a source and a drain of the transistor M307 is connected to the terminal V1. The other of the source and the drain of the transistor M307 is connected to one of a source and a drain of the transistor M308, a gate of the transistor M309, a gate of the transistor M310, and a gate of the transistor M314. The other of the source and the drain of the transistor M308 is connected to the terminal V2. One of a source and a drain of the transistor M309 is connected to the terminal V1. The other of the source and the drain of the transistor M309 is connected to one of a source and a drain of the transistor M310, a gate of the transistor M311, and a gate of the transistor M312. The other of the source and the drain of the transistor M310 is connected to the terminal V2. One of a source and a drain of the transistor M311 is connected to the terminal IT31. The other of the source and the drain of the transistor M311 is connected to one of a source and a drain of the transistor M312, the terminal OT32, and the other of the source and the drain of the transistor M314. The other of the source and the drain of the transistor M312 is connected to the terminal V2.

The transistor of one embodiment of the present invention can use transistors with various structures. For example, any of transistors with various structures such as a planar type, a Fin-type, a top-gate type, a bottom-gate type, or a vertical transistor can be used. In addition, a MOS transistor, a junction transistor, a bipolar transistor, or the like can be used as the transistor of one embodiment of the present invention.

A variety of semiconductor materials can be used for the semiconductor layer of the transistor of one embodiment of the present invention; for example, a single semiconductor such as silicon or germanium, a compound semiconductor such as silicon carbide or gallium arsenide, or an oxide semiconductor, which is a kind of compound semiconductor, can be used.

### Operation Example

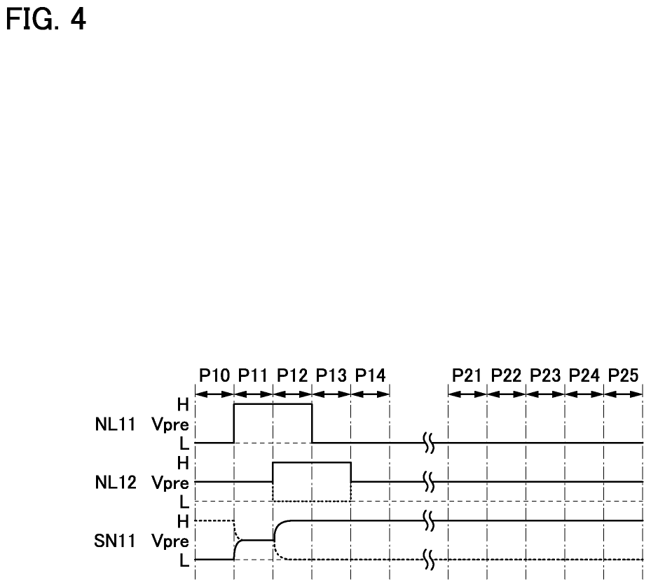

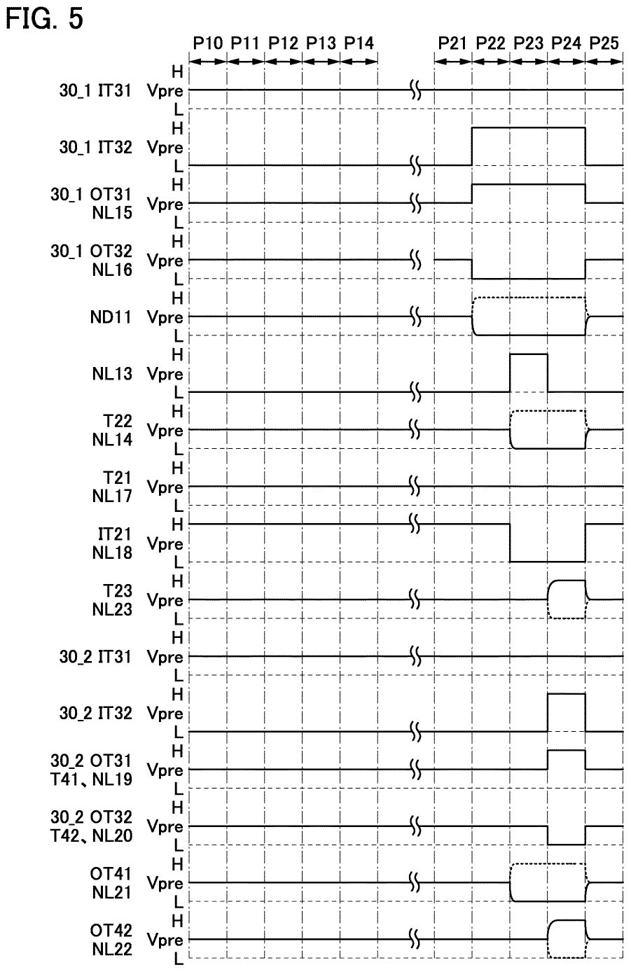

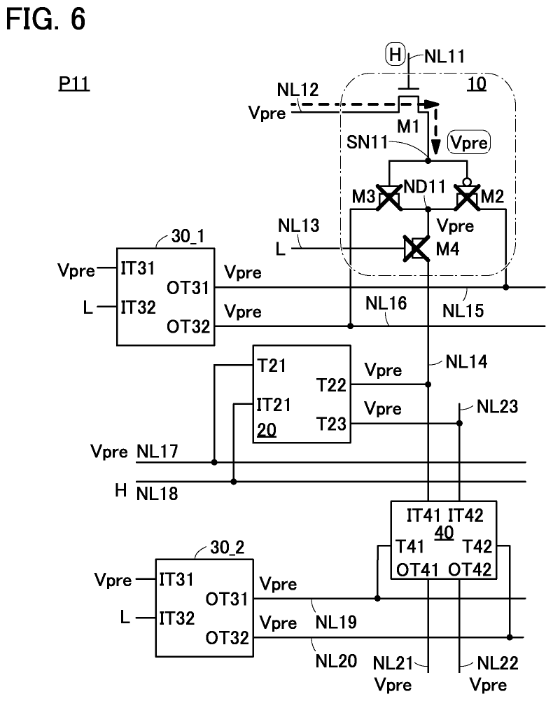

Next, an example of data writing operation and data reading operation of the semiconductor device including the memory cell 10 shown in FIG. 1A are described. Here, an operation example in which data “1” is written to the memory cell 10 and an operation example in which data “1” is read from the memory cell 10 are described. A normally-off transistor is used as the transistor included in the semiconductor device including the memory cell 10. FIGS. 4 and 5 are each a timing chart for describing the operation example of the semiconductor device including the memory cell 10. In FIGS. 4 and 5, P10 to P14 represent periods in writing operation. Furthermore, P21 to P25 in FIGS. 4 and 5 represent periods in the reading operation. In the timing chart, “H” represents a potential H. Similarly, “L” represents a potential L. Furthermore, “Vpre” represents the potential Vpre. The potential Vpre is lower than the potential H and higher than the potential L. The potential Vpre is preferably a potential intermediate between the potential H and the potential L. Note that waveforms of the operation example in which the data “1” is written to the memory cell 10 and the operation example in which the data “1” is read from the memory cell 10 are shown by solid lines. In an operation example in which data “0” is written to the memory cell 10 and an operation example in which data “0” is read from the memory cell 10, waveforms that are different from the waveforms of the writing operation and the reading operation of the data “1” are indicated by dashed lines. FIGS. 6 to 14 are circuit diagrams for describing an operation example of the semiconductor device including the memory cell 10.

### Data Writing Operation

First, an operation example in which the data “1” is written to the semiconductor device including the memory cell 10 is described. In the data writing operation in this embodiment, an operation example in which data is written to the node SN11 is described.

In a state just before the operation of writing the data “1” (the period P10 in FIG. 4), the potential of the wiring NL11 is the potential L, the potential of the wiring NL12 is the potential Vpre, and the potential of the node SN11 is the potential L. At this time, the transistor M2 is in an on state. The potential Vpre from the terminal OT31 of the circuit 30_1 is supplied to the node ND11 through the wiring NL15. The potential L is supplied to a gate of the transistor M4 through the wiring NL13. Thus, the transistor M4 is in an off state.

In the period P10 to the period P14, as shown in FIG. 5, the potentials of the terminal IT31 of the circuit 30_1, the terminal OT31 of the circuit 30_1, the wiring NL15, the terminal OT32 of the circuit 30_1, the wiring NL16, the node ND11, the terminal T22, the wiring NL14, the terminal T21, the wiring NL17, the terminal T23, the wiring NL23, the terminal IT31 of the circuit 30_2, the terminal OT31 of the circuit 30_2, the terminal T41, the wiring NL19, the terminal OT32 of the circuit 30_2, the terminal T42, the wiring NL20, the terminal OT41, the wiring NL21, the terminal OT42, and the wiring NL22 are each the potential Vpre. The potentials of the terminal IT32 of the circuit 30_1, the wiring NL13, and the terminal IT32 of the circuit 30_2 are each the potential L. The potentials of the terminal IT21 and the wiring NL18 are each the potential H.

In the period P11 (see FIG. 4 and FIG. 6), the potential H is supplied to the wiring NL11. Then, the transistor M1 is turned on, and the potential of the node SN11 becomes the potential Vpre.

The potential Vpre is supplied to the terminal IT31 of the circuit 30_1, and the potential L is supplied to the terminal IT32 of the circuit 30_1. The potential Vpre from the terminal OT31 of the circuit 30_1 is supplied to the wiring NL15. The potential Vpre from the terminal OT32 of the circuit 30_1 is supplied to the wiring NL16.

The transistors M2 and M3 are turned off.

The potential of the node ND11 is kept at the potential Vpre.

The potential L is supplied to the gate of the transistor M4 through the wiring NL13, so that the transistor M4 is kept in an off state.

The potential H is supplied to the terminal IT21 of the circuit 20 through the wiring NL18. The potential Vpre is supplied to the terminal T21 of the circuit 20 through the wiring NL17. The potential Vpre from the terminal T22 of the circuit 20 is supplied to the wiring NL14. The potential Vpre from the terminal T23 of the circuit 20 is supplied to the wiring NL23.

The potential Vpre is supplied to the terminal IT41 of the circuit 40 through the wiring NL14. The potential Vpre is supplied to the terminal IT42 of the circuit 40 through the wiring NL23. Note that the wiring NL23 corresponds to the wiring NL14 of an adjacent memory cell.

The potential Vpre is supplied to the terminal IT31 of the circuit 30_2, and the potential L is supplied to the terminal IT32 of the circuit 30_2. The potential Vpre from the terminal OT31 of the circuit 30_2 is supplied to the wiring NL19. The potential Vpre from the terminal OT32 of the circuit 30_2 is supplied to the wiring NL20.

The potential Vpre from the terminal OT31 of the circuit 30_2 is supplied to the terminal T41 of the circuit 40 through the wiring NL19. The potential Vpre from the terminal OT32 of the circuit 30_2 is supplied to the terminal T42 of the circuit 40 through the wiring NL20.

The potential Vpre from the terminal OT41 of the circuit 40 is supplied to the wiring NL21, and the potential Vpre from the terminal OT42 of the circuit 40 is supplied to the wiring NL22.

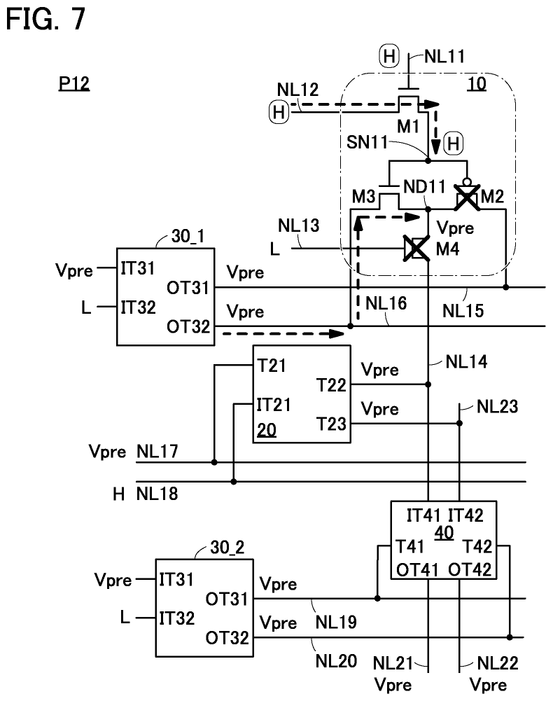

In the period P12 (see FIG. 4 and FIG. 7), the potential H is supplied to the wiring NL11 and the potential H is supplied to the wiring NL12. The transistor M1 is kept in an on state, and the potential of the node SN11 becomes the potential H.

When the potential of the node SN11 becomes the potential H, the transistor M3 is turned on, whereas the transistor M2 is kept in an off state. Thus, the potential of the node ND11 is kept at the potential Vpre.

In the period P12, the potential Vpre from the terminal T22 of the circuit 20 is supplied to the wiring NL14.

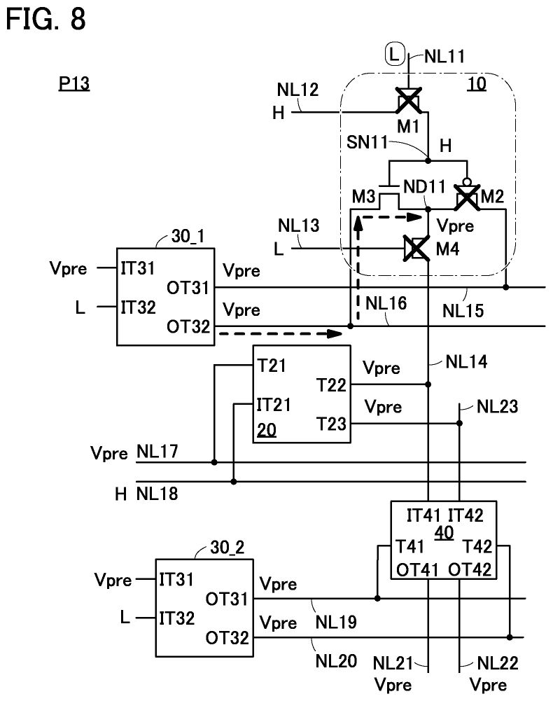

In the period P13 (see FIG. 4 and FIG. 8), the potential L is supplied to the wiring NL11. Then, the transistor M1 is turned off, and the potential of the node SN11 is held at the potential H.

The transistor M2 is kept in an off state and the transistor M3 is kept in an on state.

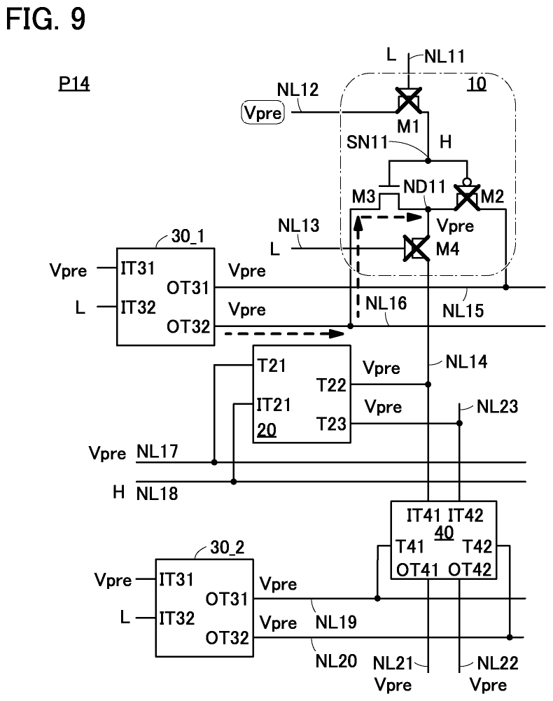

In the period P14 (see FIG. 4 and FIG. 9), the potential L is supplied to the wiring NL11, and the potential Vpre is supplied to the wiring NL12. The transistor M1 is kept in an off state, and the potential of the node SN11 is held at the potential H.

As described above, the OS transistor has an extremely low off-state current. When the OS transistor is used as the transistor M1, the data written to the node SN11 can be held for a long period. Thus, refresh operation for the node SN11 can be omitted, and the power consumption of the semiconductor device including the memory cell 10 can be reduced.

### Reading Operation

Next, an operation example in which data held in the memory cell 10 is read will be described. In this embodiment, an example of a reading operation in the case where the potential H corresponding to the data “1” is held in the memory cell 10 is described.

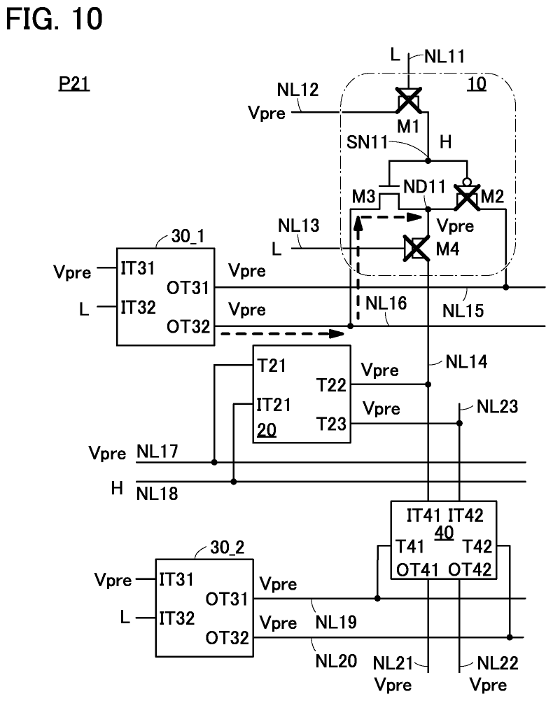

Potentials of the wirings, the terminals, and the nodes in the period P21 (see FIG. 5 and FIG. 10) are in the same state as those in the period P14 (see FIG. 4 and FIG. 9). In the period P21 to the period P25, the potential of the wiring NL11 is the potential L as shown in FIG. 4. The potential of the wiring NL12 is the potential Vpre. The potential of the node SN11 is the potential H.

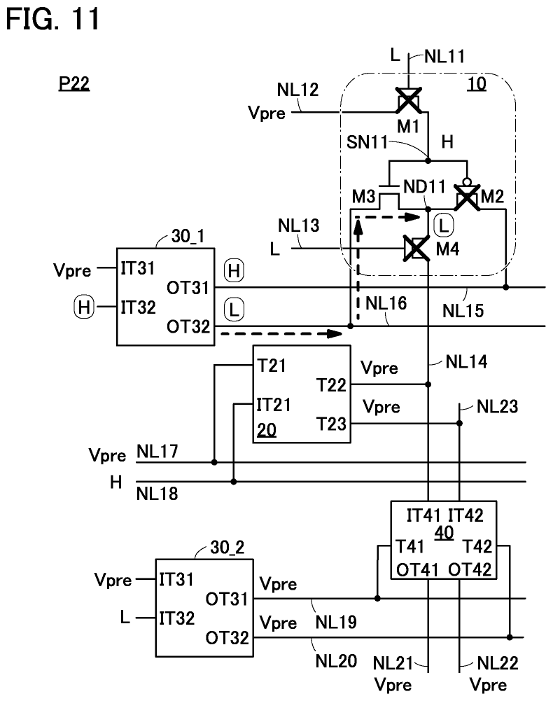

In the period P22 (see FIG. 5 and FIG. 11), the transistor M1 is kept in an off state, and thus the potential of the node SN11 is held at the potential H.

The potential Vpre is supplied to the terminal IT31 of the circuit 30_1, and the potential H is supplied to the terminal IT32 of the circuit 30_1. The potential H from the terminal OT31 of the circuit 30_1 is supplied to the wiring NL15. The potential L from the terminal OT32 of the circuit 30_1 is supplied to the wiring NL16.

The transistor M2 is kept in an off state and the transistor M3 is kept in an on state.

Since the transistor M3 is in an on state, the potential L is supplied to the node ND11 through the source and the drain of the transistor M3.

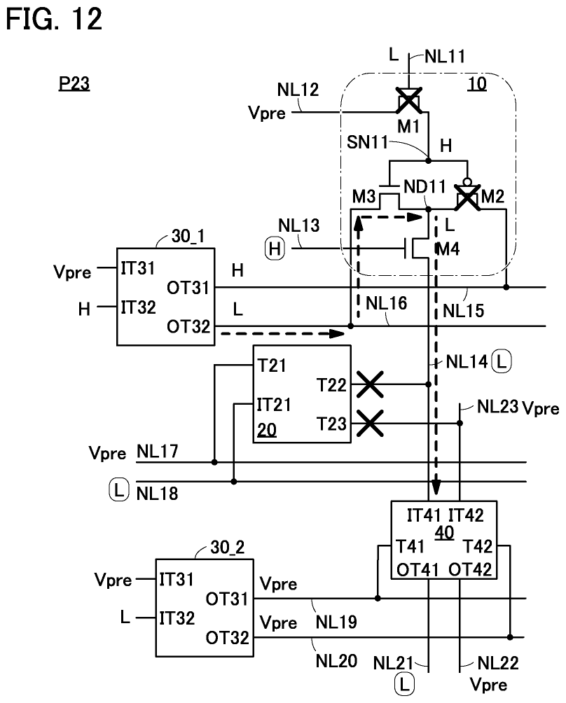

In the period P23 (see FIG. 5 and FIG. 12), the potential L is supplied to the terminal IT21 of the circuit 20 through the wiring NL18. The potential Vpre is supplied to the terminal T21 of the circuit 20 through the wiring NL17. Accordingly, a potential from the terminal T22 of the circuit 20 is not supplied to the wiring NL14. In other words, electrical continuity is not established between the terminal T22 of the circuit 20 and another wiring inside the circuit 20. Furthermore, a potential from the terminal T23 of the circuit 20 is not supplied to the wiring NL23 either. In other words, the terminal T23 of the circuit 20 is brought into a non-conduction state with another wiring inside the circuit 20.

The potential H is supplied to the gate of the transistor M4 through the wiring NL13, whereby the transistor M4 is turned on.

The potential of the node ND11 is kept at the potential L; when the transistor M4 is turned on, the potential L is supplied to the terminal IT41 of the circuit 40 through the wiring NL14. The potential L is supplied to the wiring NL21 from the terminal OT41 of the circuit 40. The potential Vpre is supplied to the terminal IT42 of the circuit 40 through the wiring NL23.

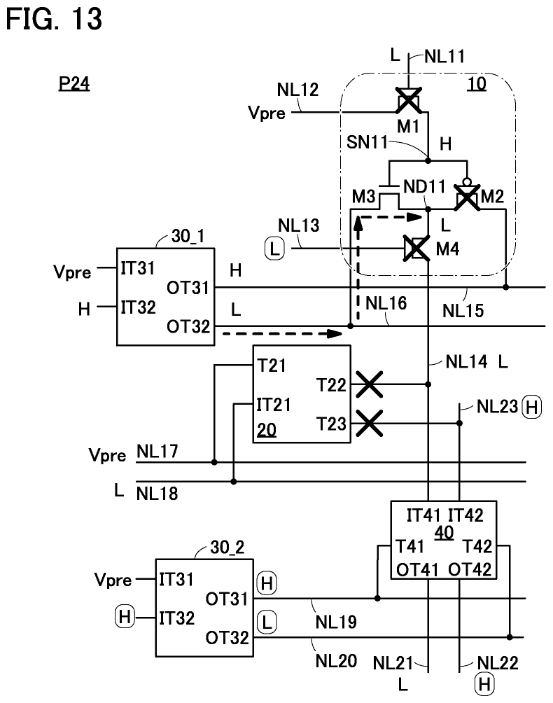

In the period P24 (see FIG. 5 and FIG. 13), the transistor M1 is kept in an off state, and thus the potential of the node SN11 is held at the potential H.

The potential L is supplied to the gate of the transistor M4 through the wiring NL13, whereby the transistor M4 is turned off. The potential of the wiring NL14 becomes the potential L.

The potential Vpre is supplied to the terminal IT31 of the circuit 30_2, and the potential H is supplied to the terminal IT32 of the circuit 30_2. The potential H from the terminal OT31 of the circuit 30_2 is supplied to the wiring NL19. The potential L from the terminal OT32 of the circuit 30_2 is supplied to the wiring NL20. Thus, the potential H from the terminal OT31 of the circuit 30_2 is supplied to the terminal T41 of the circuit 40 through the wiring NL19. The potential L from the terminal OT32 of the circuit 30_2 is supplied to the terminal T42 of the circuit 40 through the wiring NL20.

When the circuits shown in FIGS. 2D and 2E are used as the circuit 40, the potential of the wiring NL23 becomes the potential H when the potential of the wiring NL14 is the potential L as shown in FIG. 13. The potential difference between the wiring NL14 and the wiring NL23 is amplified to a power supply voltage supplied to the circuit 40, and then output. Specifically, the potential L of the wiring NL14 can be set to the low power supply potential VSS. In addition, the potential H of the wiring NL23 can be set to the high power supply potential VDD. Accordingly, the potential L from the terminal OT41 of the circuit 40 is supplied to the wiring NL21, and the potential H from the terminal OT42 of the circuit 40 is supplied to the wiring NL22. With the use of the circuit 40, the potential H and the potential L can be surely output to the terminal OT41 and the terminal OT42 in accordance with the potential of the wiring NL14 and the wiring NL23 that can function as bit lines.

As a result, a signal corresponding to the data held in the node SN11 can be read from the wiring NL22.

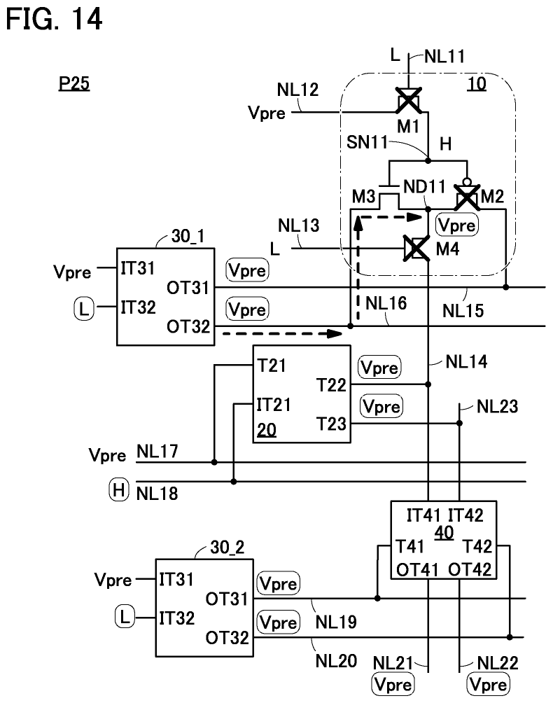

Potentials of the wirings, the terminals, and the nodes in the period P25 (see FIG. 5 and FIG. 14) are in the same state as those in the period P21 (see FIG. 5 and FIG. 10).

The semiconductor device including the memory cell 10 of one embodiment of the present invention functions as a memory cell in which charge is written to the node SN11 through the transistor M1. Accordingly, high voltage, which is necessary for a flash memory, is unnecessary and high-speed writing operation can be achieved, for example. Furthermore, the semiconductor device including the memory cell 10 does not perform charge injection and extraction to and from a floating gate or a charge-trap layer, and thus substantially has no limitation on the number of times of data writing and reading. Unlike in a flash memory, unstableness due to an increase of electron trap centers is not observed in the semiconductor device including the memory cell 10 even when rewriting operation is repeated. The semiconductor device including the memory cell 10 of one embodiment of the present invention is less likely to degrade than a conventional flash memory and can have high reliability. In particular, the use of an OS transistor as the transistor M1 enables long-term data holding even in a high-temperature environment; thus, high reliability can be obtained even in a high-temperature environment.

In the semiconductor device including the memory cell 10 of one embodiment of the present invention, when the wiring NL14 and the wiring NL23 are connected to the circuit 20 that can function as a precharge circuit, the potential of the wiring NL14 connected to the node ND11 can be set to the potential Vpre before data reading. The potential Vpre is preferably, for example, a potential intermediate between the potential H and the potential L, a potential of VDD/2, or a potential intermediate between VDD and VSS. Thus, at the time of data reading, the amount of charge written to the wiring NL14 (a change in the potential of the wiring NL14) can be smaller than the amount of potential change from the potential H to the potential L (or from the potential L to the potential H). Accordingly, data reading time can be shortened. Moreover, power consumption for charging and discharging of one or both of the wirings NL14 and NL23 that can function as bit lines to be reduced.

The memory cell 10 of one embodiment of the present invention functions as a memory element capable of non-destructive read. In the memory cell 10 of one embodiment of the present invention, the reading portion 10b functions as an inverter. Thus, the potential H or the potential L can be surely output in accordance with the held data. For example, when an inverter of a complementary MOS transistor is used, either an n-type transistor or a p-type transistor can operate in accordance with the potential of the node SN11; thus, the range of a potential of data held in the node SN11 can be widened. Even when the potential of the held data is slightly changed by noise or the like, the potential H or the potential L can be surely output in accordance with the held data. In addition, a potential decrease of an output signal due to parasitic capacitance or the like is less likely to occur. In the memory cell 10 of one embodiment of the present invention, a change in output signal due to noise, parasitic capacitance, or the like is less likely to occur, and the held data can be stably read. By including the memory cell 10 of one embodiment of the present invention, a semiconductor device such as a memory device can have higher reliability.

When the circuit 40 that can function as a sense amplifier is connected to the wiring NL14 and the wiring NL23, the voltage amplitude of the data signal to be read can be increased and data can be read more stably.

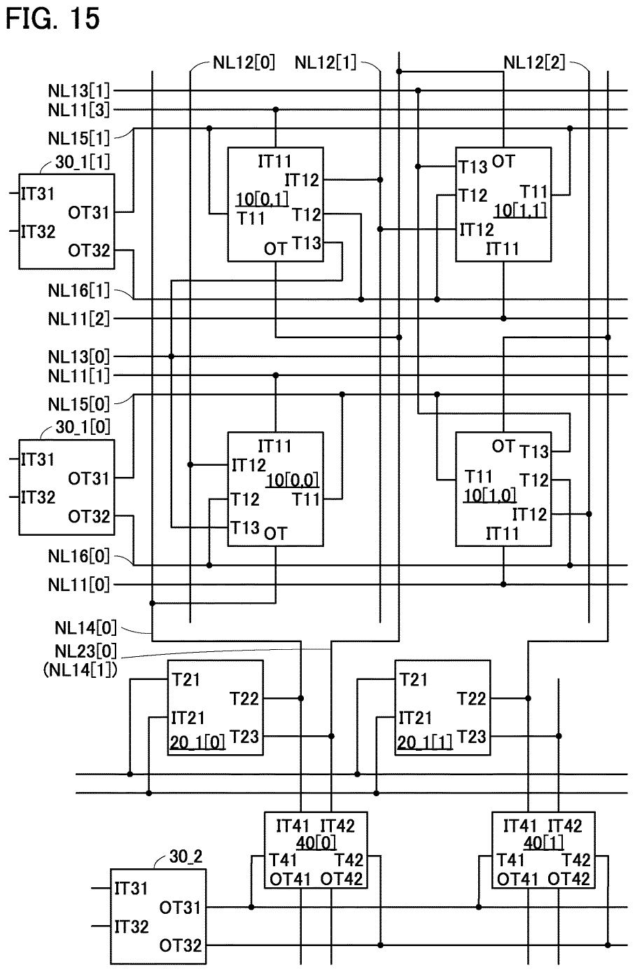

FIG. 15 shows an example of a semiconductor device in which the memory cells 10 are arranged in a lattice pattern. In FIG. 15, a memory cell 10[0, 1] is placed adjacent to a memory cell 10[0, 0] in the Y direction, a memory cell 10[1, 0] is placed adjacent to the memory cell 10[0, 0] in the X direction, and a memory cell 10[1, 1] is placed adjacent to the memory cell 10[0, 1] in the X direction and adjacent to the memory cell 10[1, 0] in the Y direction. Although FIG. 15 shows an example in which two rows and two columns of the memory cells 10 are arranged in a lattice pattern, one embodiment of the present invention is not limited thereto.

The plurality of memory cells 10 arranged in a lattice pattern can share wirings. For example, a wiring NL12[1] can be connected to at least the terminal IT12 of the memory cell 10[0, 1] and the terminal IT12 of the memory cell 10[1, 1]. A wiring NL23[0] (NL4[1]) can be connected to at least the terminal OT of the memory cell 10[0, 1] and the terminal OT of the memory cell 10[1, 1]. A wiring NL13[0] can be connected to at least the terminal T13 of the memory cell 10[0, 0] and the terminal T13 of the memory cell 10[0, 1]. A wiring NL13[1] can be connected to at least the terminal T13 of the memory cell 10[1, 1] and the terminal T13 of the memory cell 10[1, 0].

The terminal OT of the memory cell 10[0, 0] is connected to the terminal IT41 of a circuit 40[0] through a wiring NL14[0]. The terminal OT of the memory cell 10[0, 1] is connected to the terminal IT42 of the circuit 40[0] through the wiring NL23[0] (NL4[1]).

At least part of this embodiment can be implemented as appropriate in combination with any of the other embodiments described in this specification. In this specification, in the case where a plurality of structure examples or modification examples are shown in one embodiment, the structure examples and modification examples can be combined as appropriate.

### Embodiment 2

In this embodiment, a transistor that can be used for a semiconductor device including the memory cell 10 of one embodiment of the present invention will be described.

In the memory cell 10 of one embodiment of the present invention, the transistor M1, the transistor M2, and the transistor M3 may be provided to overlap with each other. Providing the transistors to overlap with each other enables the area occupied by the memory cell 10 to be reduced. Thus, a more highly integrated semiconductor device can be provided.

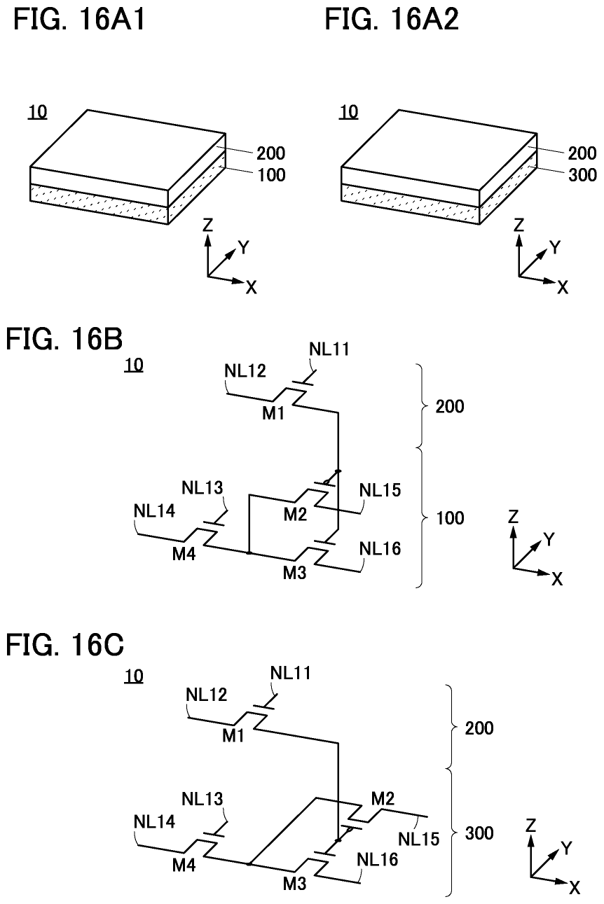

FIG. 16A1 and 16A2 are perspective conceptual diagrams of the memory cell 10. FIGS. 16B and 16C are perspective conceptual diagrams for describing further details of the structure of the memory cell 10.

As shown in FIG. 16A1, the memory cell 10 includes an element layer 200 overlapping with an element layer 100. Alternatively, as shown in FIG. 16A2, the memory cell 10 includes the element layer 200 overlapping with an element layer 300. Transistors formed in the element layer 100 and the element layer 300 are preferably Si transistors, and a transistor formed in the element layer 200 is preferably an OS transistor.

As shown in FIG. 16B, in the memory cell 10, the element layer 100 can include the transistor M3, the transistor M4, and the transistor M2 which overlaps with the transistor M3, and the element layer 200 can include the transistor M1, for example. The transistor M2 and the transistor M1 may be provided to overlap with each other. As shown in FIG. 16C, in the memory cell 10, the element layer 300 can include the transistor M3, the transistor M4, and the transistor M2 and the element layer 200 can include the transistor M1, for example. An n-type Si transistor is preferably used as each of the transistors M3 and M4. A p-type Si transistor is preferably used as the transistor M2. An n-type OS transistor is preferably used as the transistor M1.

### Structure Example of Semiconductor Device

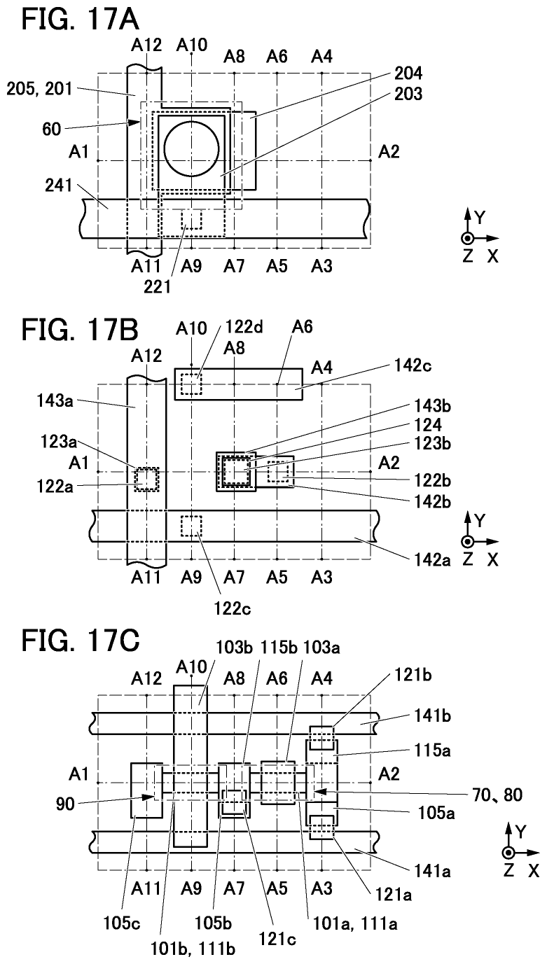

FIGS. 17A to 17C and FIGS. 18 to 23 show examples of schematic top views and schematic cross-sectional views of the structure in FIG. 16B. FIGS. 17A to 17C are each an example of a schematic top view of the memory cell 10. Since the memory cell 10 of one embodiment of the present invention has a multilayer structure, conductor layers and semiconductor layers in different layers are separately shown in FIGS. 17A to 17C. Specifically, FIG. 17C shows a layer on a substrate side, FIG. 17B shows a layer over the layer shown in FIG. 17C, and FIG. 17A shows a layer over the layer shown in FIG. 17B.

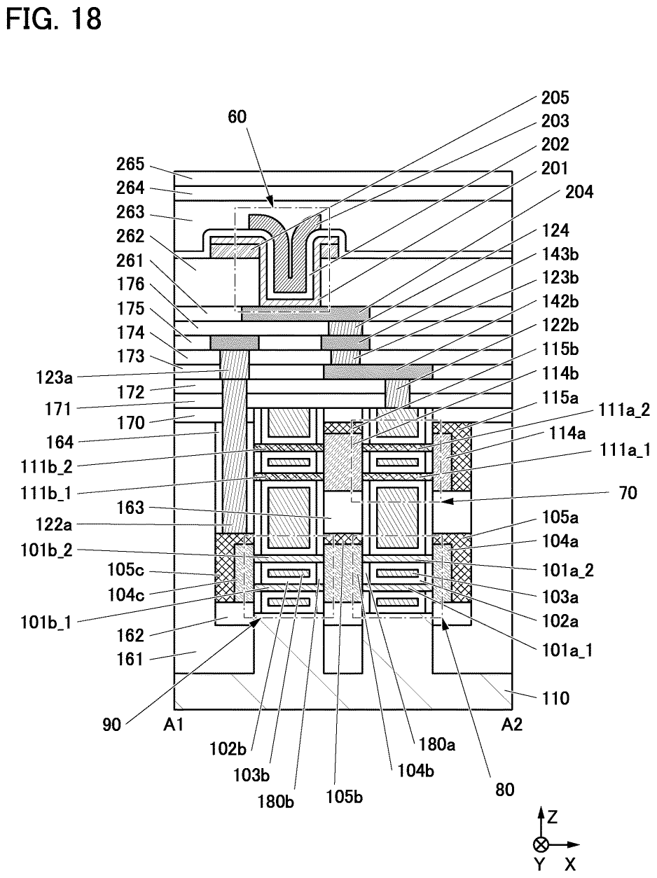

A transistor 60 shown in FIGS. 17A and 18 corresponds to the transistor M1 in FIG. 16B. A transistor 70 shown in FIGS. 17C and 18 corresponds to the transistor M2 in FIG. 16B. A transistor 80 shown in FIGS. 17C and 18 corresponds to the transistor M3 in FIG. 16B. A transistor 90 shown in FIGS. 17C and 18 corresponds to the transistor M4 in FIG. 16B.

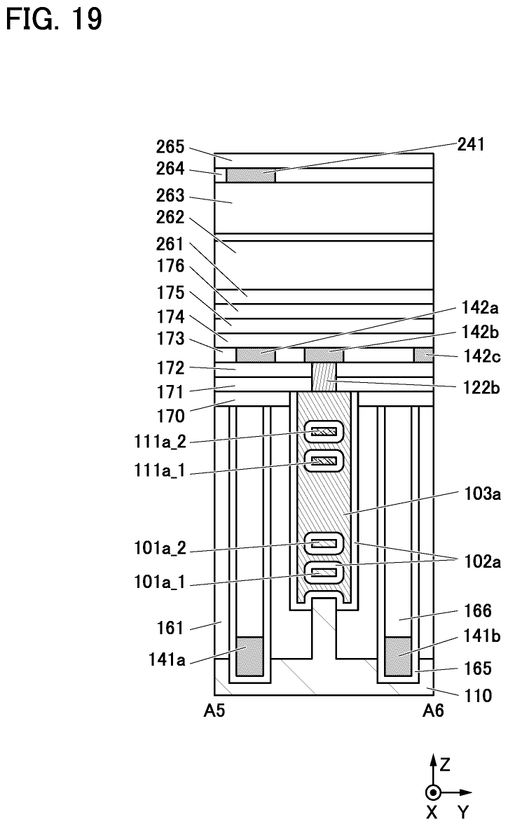

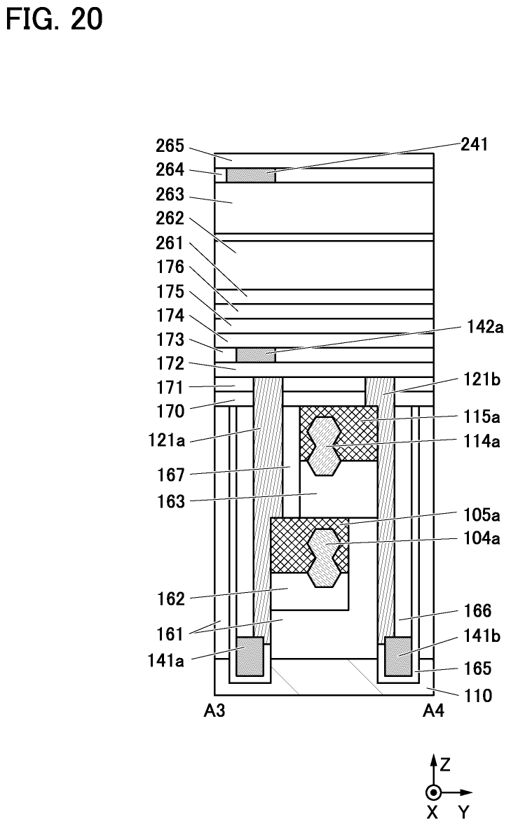

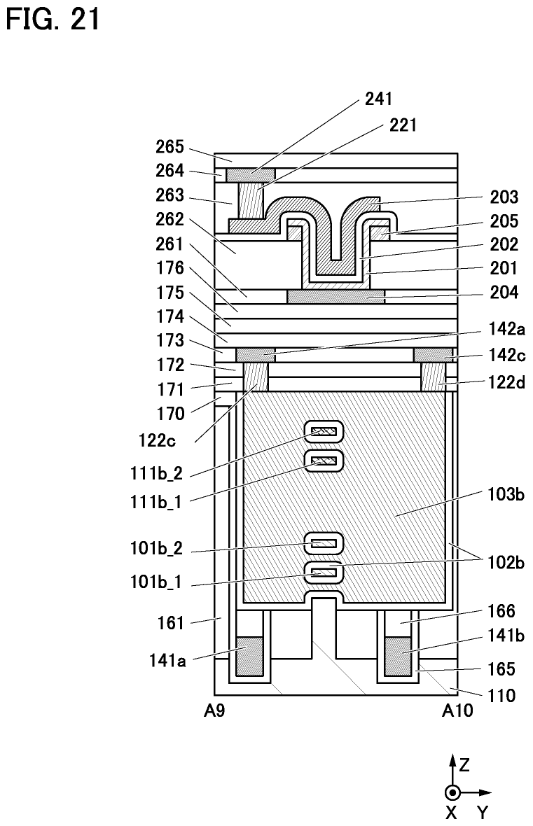

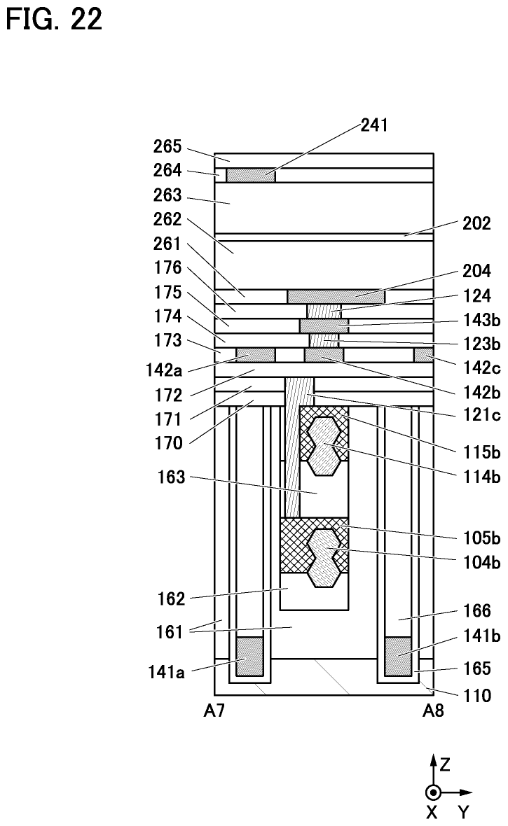

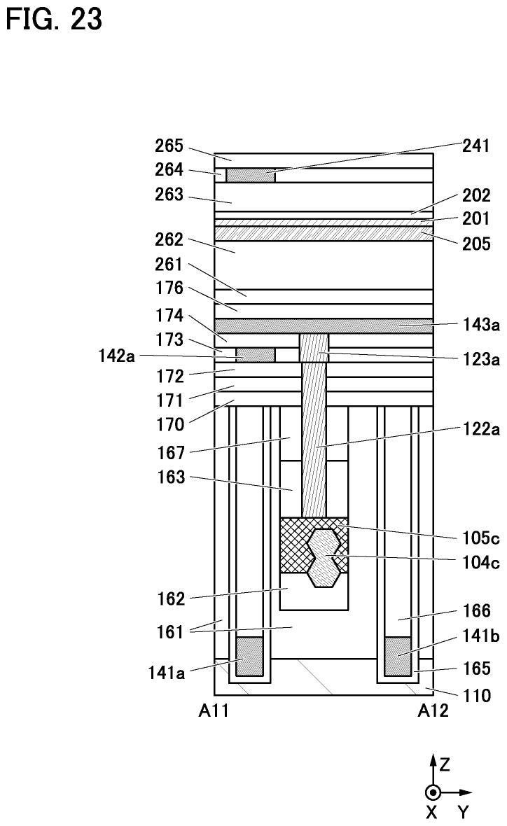

FIG. 18 is a schematic cross-sectional view taken along the dashed-dotted line A1-A2 in FIGS. 17A to 17C. FIG. 19 is a schematic cross-sectional view taken along the dashed-dotted line A5-A6 in FIGS. 17A to 17C. FIG. 20 is a schematic cross-sectional view taken along the dashed-dotted line A3-A4 in FIGS. 17A to 17C. FIG. 21 is a schematic cross-sectional view taken along the dashed-dotted line A9-A10 in FIGS. 17A to 17C. FIG. 22 is a schematic cross-sectional view taken along the dashed-dotted line A7-A8 in FIGS. 17A to 17C. FIG. 23 is a schematic cross-sectional view taken along the dashed-dotted line A11-A12 in FIGS. 17A to 17C.

The transistor 80 includes at least a semiconductor 101a (a semiconductor 101a_1 and a semiconductor 101a_2), a conductor 104a, a conductor 104b, an insulator 102a, and a conductor 103a. The conductor 103a is provided to surround a top surface, a bottom surface, and a pair of opposite side surfaces of the semiconductor 101a (the semiconductor 101a_1 and the semiconductor 101a_2). The insulator 102a is provided to be positioned between the conductor 103a and the semiconductor 101a (the semiconductor 101a_1 and the semiconductor 101a_2). The conductor 104a includes a region in contact with the semiconductor 101a. Specifically, the conductor 104a includes a region in contact with the semiconductor 101a_1 and a region in contact with the semiconductor 101a_2. The conductor 104b includes a region in contact with the semiconductor 101a. Specifically, the conductor 104b includes a region in contact with the semiconductor 101a_1 and a region in contact with the semiconductor 101a_2.

Single crystal silicon is preferably used for the semiconductor 101a (the semiconductor 101a_1 and the semiconductor 101a_2).

When Si is used for the semiconductor 101, an epitaxially grown silicide on the Si is preferably used for the conductor 104. For example, silicide containing an impurity element such as phosphorus is preferably used for the conductor 104.

A conductor 105a includes a region in contact with the conductor 104a. A conductor 105b includes a region in contact with the conductor 104b.

Part or the whole of the semiconductor 101a (the semiconductor 101a_1 and the semiconductor 101a_2) can function as a channel formation region of the transistor 80. Part or the whole of the conductor 104a can function as one of a source region and a drain region of the transistor 80. Part or the whole of the conductor 104b can function as the other of the source region and the drain region of the transistor 80. Part or the whole of the insulator 102a can function as a gate insulating film of the transistor 80. Part or the whole of the conductor 103a can function as a gate electrode of the transistor 80.

The transistor 70 includes at least a semiconductor 111a (a semiconductor111a_1 and a semiconductor 111a_2), a conductor 114a, a conductor 114b, the insulator 102a, and the conductor 103a. The conductor 103a is provided to surround a top surface, a bottom surface, and a pair of opposite side surfaces of the semiconductor 111a (the semiconductor 111a_1 and the semiconductor 111a_2). The insulator 102a is provided to be positioned between the conductor 103a and the semiconductor 111a (the semiconductor 111a_1 and the semiconductor 111a_2). The conductor 114a includes a region in contact with the semiconductor 111a. Specifically, the conductor 114a includes a region in contact with the semiconductor 111a_1 and a region in contact with the semiconductor 111a_2. The conductor 114b includes a region in contact with the semiconductor 111a. Specifically, the conductor 114b includes a region in contact with the semiconductor 111a_1 and a region in contact with the semiconductor 111a_2.

Single crystal silicon is preferably used for the semiconductor 111a (the semiconductor 111a_1 and the semiconductor 111a_2).

When Si is used for the semiconductor 111, an epitaxially grown silicide on the Si is preferably used for the conductor 114. For example, silicide containing an impurity element such as boron is preferably used for the conductor 114.

A conductor 115a includes a region in contact with the conductor 114a. A conductor 115b includes a region in contact with the conductor 114b.

Part or the whole of the semiconductor 111a (the semiconductor 111a_1 and the semiconductor 111a_2) can function as a channel formation region of the transistor 70. Part or the whole of the conductor 114b can function as one of a source region and a drain region of the transistor 70. Part or the whole of the conductor 114a can function as the other of the source region and the drain region of the transistor 70. Part or the whole of the insulator 102a can function as a gate insulating film of the transistor 70. Part or the whole of the conductor 103a can function as a gate electrode of the transistor 70.

The transistor 90 includes at least a semiconductor 101b (a semiconductor 101b_1 and a semiconductor 101b_2), the conductor 104b, a conductor 104c, an insulator 102b, and a conductor 103b. The conductor 103b is provided to surround a top surface, a bottom surface, and a pair of opposite side surfaces of the semiconductor 101b (the semiconductor 101b_1 and the semiconductor 101b_2). The insulator 102b is provided to be positioned between the conductor 103b and the semiconductor 101b (the semiconductor 101b_1 and the semiconductor 101b_2). The conductor 104b includes a region in contact with the semiconductor 101b. Specifically, the conductor 104b includes a region in contact with the semiconductor 101b_1 and a region in contact with the semiconductor 101b_2. The conductor 104c includes a region in contact with the semiconductor 101b. Specifically, the conductor 104c includes a region in contact with the semiconductor 101b_1 and a region in contact with the semiconductor 101b_2.

Single crystal silicon is preferably used for the semiconductor 101b (the semiconductor 101b_1 and the semiconductor 101b_2).

A conductor 105c includes a region in contact with the conductor 104c. The conductor 105b includes a region in contact with the conductor 104b.

Part or the whole of the semiconductor 101b (the semiconductor 101b_1 and the semiconductor 101b_2) can function as a channel formation region of the transistor 90. Part or the whole of the conductor 104b can function as one of a source region and a drain region of the transistor 90. Part or the whole of the conductor 104c can function as the other of the source region and the drain region of the transistor 90. Part or the whole of the insulator 102b can function as a gate insulating film of the transistor 90. Part or the whole of the conductor 103b can function as a gate electrode of the transistor 90.

The transistor 60 includes at least a semiconductor 201, a conductor 204, a conductor 205, an insulator 202, and a conductor 203. The semiconductor 201 includes a region in contact with the conductor 205. The semiconductor 201 includes, in an opening portion provided in an insulator 262, a region in contact with the side surface of the insulator 262 and a region in contact with the conductor 204. The conductor 203 includes a region positioned in the opening portion provided in the insulator 262. The semiconductor 201 positioned in the opening portion provided in the insulator 262 includes a region provided to surround the conductor 203 in a plan view. The insulator 202 is provided to be positioned between the semiconductor 201 and the conductor 203 in the opening portion provided in the insulator 262.

As the semiconductor 201, a metal oxide exhibiting semiconductor characteristics (an oxide semiconductor) is preferably used.

Part or the whole of the semiconductor 201 can function as a channel formation region of the transistor 60. Part or the whole of the conductor 205 can function as one of a source region and a drain region of the transistor 60. Part or the whole of the conductor 204 can function as the other of the source region and the drain region of the transistor 60. Part or the whole of the insulator 202 can function as a gate insulating film of the transistor 60. Part or the whole of the conductor 203 can function as a gate electrode of the transistor 60.

FIG. 18 is a schematic cross-sectional view including cross sections of the transistor 60, the transistor 70, the transistor 80, and the transistor 90 in the channel length direction. FIG. 19 and FIG. 21 are schematic cross-sectional views including cross sections of the transistor 70, the transistor 80, and the transistor 90 in the channel width direction.

As shown in FIGS. 18, 19, and 21, the semiconductor 111a (the semiconductor 111a_1 and the semiconductor 111a_2) that can function as the channel formation region of the transistor 70 includes a region overlapping with the semiconductor 101a (the semiconductor 101a_1 and the semiconductor 101a_2) that can function as the channel formation region of the transistor 80. The conductor 103a can function as the gate electrode of each of the transistors 70 and 80. The insulator 102a can function as the gate insulating film of each of the transistors 70 and 80.

The transistors 70 and 80 can share some components in this manner, whereby the manufacturing process of the transistors can be simplified and the yield can be improved.

The conductor 104b can function as the other of the source region and the drain region of the transistor 80 and one of the source region and the drain region of the transistor 90.

The transistors 80 and 90 can share some components in this manner, whereby the manufacturing process of the transistors can be simplified and the yield can be improved.

The semiconductor 201 that can function as the channel formation region of the transistor 60 includes a region overlapping with the semiconductor 101b (the semiconductor 101b_1 and the semiconductor 101b_2) that can function as the channel formation region of the transistor 90.

An insulator 180a is provided between the conductor 104b and the insulator 102a and between the conductor 104a and the insulator 102a. An insulator 180b is provided between the conductor 104b and the insulator 102b and between the conductor 104c and the insulator 102b. The insulator 180a is provided between the conductor 114b and the insulator 102a and between the conductor 114a and the insulator 102a. The insulator 180b is provided between the conductor 114b and the insulator 102b. With the insulator 180, the conductor 104 can be apart from the conductor 103, and the parasitic capacitance generated between the conductor 104 and the conductor 103 can be reduced.

Note that a semiconductor 111b (a semiconductor 111b_1 and a semiconductor 111b_2) is provided over the semiconductor 101b to overlap with each other. The conductor 103b is provided to surround a top surface, a bottom surface, and a pair of opposite side surfaces of the semiconductor 111b (the semiconductor 111b_1 and the semiconductor 111b_2). The insulator 102b is provided to be positioned between the conductor 103b and the semiconductor 111b (the semiconductor 111b_1 and the semiconductor 111b_2). Although one side of each of the semiconductors 111b_1 and 111b_2 is in contact with the conductor 114b, the other side of each of the semiconductors 111b_1 and 111b_2 is not in contact with the conductor but in contact with an insulator 164. Accordingly, the semiconductors 111b_1 and 111b_2 do not each function as a channel formation region of a transistor since only one of a source and a drain of the transistor is formed, and thus the semiconductors 111b_1 and 111b_2 are provided as dummy components.

In the semiconductor device of one embodiment of the present invention, the transistor 70 (a p-type Si transistor) and the transistor 80 (an n-type Si transistor) can be formed to overlap with each other. Alternatively, the transistor 60 (an OS transistor) can be formed above the transistor 70 (a p-type Si transistor) and the transistor 80 (an n-type Si transistor). Alternatively, the transistor 60 (an OS transistor) can be formed to overlap with the transistor 90 (an n-type Si transistor). Thus, the memory cell 10 that occupies a small area can be formed. In addition, a memory device in which memory cells are arranged at high density can be achieved.

Although an example in which the transistor 70 (a p-type Si transistor) is formed over the transistor 80 (an n-type Si transistor) to overlap with each other in the semiconductor device of one embodiment of the present invention is described, one embodiment of the present invention is not limited thereto. The transistor 80 (an n-type Si transistor) may be formed over the transistor 70 (a p-type Si transistor) to overlap with each other.

As shown in FIGS. 18, 19, and 21, a gate electric field is applied to surround the channel formation region of each of the transistor 70, the transistor 80, and the transistor 90, whereby the on/off controllability of the transistors can be increased. Specifically, effects of increasing the source-drain current in an on state (on-state current) and reducing the leakage current in an off state (off-state current) can be obtained.

Note that the semiconductor 101a (the semiconductor 101a_1 and the semiconductor 101a_2) of the transistor 80, the semiconductor 111a (the semiconductor 111a_1 and the semiconductor 111a_2) of the transistor 70, and the semiconductor 101b (the semiconductor 101b_1 and the semiconductor 101b_2) of the transistor 90 preferably have a sheet-like shape. The semiconductors each are shown to have a sheet-like shape extending in the horizontal direction (direction along the XY plane) in FIGS. 18, 19, and 21; however, one embodiment of the present invention is not limited thereto, and the semiconductors may each have a sheet-like shape extending in the perpendicular direction (direction along the YZ plane), for example. The shape of the semiconductors is not limited to a sheet-like shape and may be a wire-like shape.

Although the semiconductor 101a (the semiconductor 101a_1 and the semiconductor 101a_2) of the transistor 80, the semiconductor 111a (the semiconductor 111a_1 and the semiconductor 111a_2) of the transistor 70, and the semiconductor 101b (the semiconductor 101b_1 and the semiconductor 101b_2) of the transistor 90 are each an example in which two channel formation regions of the transistor are formed using two semiconductors, one embodiment of the present invention is not limited thereto. The number of channel formation regions of each transistor may be one or three or more. For example, increasing a width of a channel formation region can increase an on-state current of a transistor; in addition, increasing the number of channel formation regions by using a plurality of layers of semiconductors can also increase the on-state current of the transistor. When the channel formation regions of the transistor are provided to overlap with each other in the above manner, the on-state current of the transistor can be increased without an increase in the area occupied by the transistor.

The conductor 103a is connected to the conductor 204 through a conductor 122b, a conductor 142b, a conductor 123b, a conductor 143b, and a conductor 124. The conductor 203 is connected to a conductor 241 through a conductor 221.

The conductor 241 can function as part or the whole of the wiring NL11 in FIG. 16B. The conductor 205 can function as part or the whole of the wiring NL12 in FIG. 16B. As shown in FIG. 17A, the conductor 241 is provided to extend in the X direction. The conductor 205 is provided to extend in the Y direction.

The conductor 103b is connected to a conductor 142a through a conductor 122c. The conductor 142a can function as part or the whole of the wiring NL13 in FIG. 16B. As shown in FIG. 17B, the conductor 142a is provided to extend in the X direction. A conductor 142c is connected to the conductor 103b through a conductor 122d.

As shown in FIG. 20, a conductor 141 (a conductor 141a and a conductor 141b) is provided to be embedded in a substrate 110 and an insulator 161. An insulator 165 is provided between the substrate 110 and the conductor 141. The insulator 165 is preferably provided in order to prevent direct contact between the conductor 141 and the substrate 110, for example, in the case where a Si substrate is used as the substrate 110 or the like.

The conductor 104a includes a region in contact with the conductor 105a and a region in contact with an insulator 162. The conductor 114a includes a region in contact with the conductor 115a and a region in contact with an insulator 163. The conductor 104a and the conductor 114a are placed to overlap with each other, and the insulator 163 is positioned therebetween.

The conductor 104a is connected to the conductor 141a through a conductor 121a. The conductor 121a is provided in an opening portion formed in a plurality of insulators such as the insulator 161, an insulator 166, an insulator 167, an insulator 170, and an insulator 171. The conductor 121a includes a region in contact with part of the top surface of the conductor 105a, a region in contact with part of a side surface of the conductor 105a, and a region in contact with part of the top surface of the conductor 141a.

The conductor 114a is connected to the conductor 141b through a conductor 121b. The conductor 121b is provided in an opening portion formed in a plurality of insulators such as the insulator 161, the insulator 166, the insulator 167, the insulator 170, and the insulator 171. The conductor 121b includes a region in contact with part of the top surface of the conductor 115a, a region in contact with part of a side surface of the conductor 115a, and a region in contact with part of the top surface of the conductor 141b.

The conductor 141a can function as part or the whole of the wiring NL16 in FIG. 16B. The conductor 141b can function as part or the whole of the wiring NL15 in FIG. 16B. As shown in FIG. 17C, the conductor 141 (the conductor 141a and the conductor 141b) is provided to extend in the X direction.

As shown in FIG. 22, the conductor 104b includes a region in contact with the conductor 105b and a region in contact with the insulator 162. The conductor 114b includes a region in contact with the conductor 115b and a region in contact with the insulator 163. The conductor 104b and the conductor 114b are placed to overlap with each other, and the insulator 163 is positioned therebetween.

The conductor 104b is connected to the conductor 114b through a conductor 121c. The conductor 121c is provided in an opening portion formed in a plurality of insulators such as the insulator 163, the insulator 170, and the insulator 171. The conductor 121c includes a region in contact with part of the top surface of the conductor 115b, a region in contact with part of a side surface of the conductor 115b, and a region in contact with part of the top surface of the conductor 105b.

As shown in FIG. 23, the conductor 104c includes a region in contact with the conductor 105c and a region in contact with the insulator 162. The conductor 105c is connected to a conductor 143a through a conductor 122a and a conductor 123a. The conductor 122a is provided in an opening portion provided in the insulator 163, the insulator 167, the insulator 170, the insulator 171, and an insulator 172. The conductor 123a is provided in an opening portion provided in an insulator 173 and an insulator 174.

The conductor 143a can function as part or the whole of the wiring NL14 in FIG. 16B. As shown in FIG. 17B, the conductor 143a is provided to extend in theY direction.

As the substrate 110, a silicon substrate or a silicon on insulator (SOI) substrate can be used, for example.

The conductors 141, 142, 143, and 241 can function as wirings. The conductors 121, 122, 123, 124, and 221 function as plugs, electrodes, or wirings. The conductors 105, 115, and 103 can function as electrodes or wirings.

The following insulators can also function as interlayer insulating films: the insulator 161, the insulator 162, the insulator 163, the insulator 164, the insulator 165, the insulator 166, the insulator 167, the insulator 170, the insulator 171, the insulator 172, the insulator 173, the insulator 174, an insulator 175, an insulator 176, an insulator 261, the insulator 262, an insulator 263, an insulator 264, and an insulator 265.

### Materials

Materials that can be used for the semiconductor device of this embodiment will be described below. Note that the layers included in the semiconductor device of this embodiment may each have a single-layer structure or a stacked-layer structure.

### Substrate

As the substrate 110 in the semiconductor device described in this embodiment, any of substrates described below can be used as appropriate.

As a substrate over which the transistor is formed, for example, an insulator substrate, a semiconductor substrate, or a conductor substrate may be used. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, gallium oxide, or gallium nitride. Other examples include the above semiconductor substrate including an insulator region, e.g., an SOI substrate. Examples of the conductor substrate include a graphite substrate, a metal substrate, an alloy substrate, and a conductive resin substrate. Other examples of the conductor substrate include a substrate including a nitride of a metal and a substrate including an oxide of a metal. Moreover, other examples of the conductor substrate include an insulator substrate provided with a conductive layer or a semiconductor layer, a semiconductor substrate provided with a conductive layer or an insulating layer, and a conductor substrate provided with a semiconductor layer or an insulating layer. Alternatively, these substrates provided with elements may be used. Examples of the elements provided over the substrates include a capacitor, a resistor, a switching element (such as a transistor), a light-emitting element, and a memory element.

### Conductor

The conductors 103, 104, 105, 121, 122, 123, 124, 141, 142, 143, 203, 204, 205, 221, and 241 of the semiconductor device described in this embodiment can each be formed using any of the following conductors as appropriate. As the above conductors of the semiconductor device, conductors having high conductivity are preferably used. These conductors are preferably formed using, for example, a metal element selected from aluminum, chromium, copper, silver, gold, platinum, tantalum, nickel, cobalt, titanium, molybdenum, tungsten, hafnium, vanadium, niobium, manganese, magnesium, zirconium, beryllium, indium, ruthenium, iridium, strontium, lanthanum, and the like; or an alloy containing any of the above metal elements. In addition, the conductors may use a nitride of the above metal element or an alloy containing the above metal element as a component, or an oxide of the above metal element or an alloy containing the above metal element as a component. For example, tantalum nitride, titanium nitride, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. These materials are preferable because they are conductors that are less likely to be oxidized or conductors that maintain the conductivity even when oxidized. Alternatively, a semiconductor having high electrical conductivity, typified by polycrystalline silicon containing an impurity element such as phosphorus, or silicide such as nickel silicide may be used. Tantalum, tantalum nitride, or the like has a barrier property against hydrogen, and thus is preferably used for the conductors.

A conductive oxide can also be used for the conductors of the semiconductor device. Examples of the conductive oxide include indium oxide, indium tin oxide (In-Sn oxide, also referred to as ITO), indium tin oxide containing silicon (In-Sn-Si oxide, also referred to as ITSO), In-Zn oxide, In-W oxide, In-W-Zn oxide, In-Ti oxide, and In-Ti-Sn oxide. A conductive oxide containing indium is particularly preferable because of its high conductivity. Alternatively, an oxide semiconductor that can be used as the semiconductor can also be used as the conductors when a carrier concentration is increased.

The conductors of the semiconductor device may have a single-layer structure or a stacked-layer structure of two or more layers using the above conductors. For example, a single-layer structure of a conductive oxide, a single-layer structure of tantalum nitride, a single-layer structure of tungsten, or the like can be used. Alternatively, a two-layer structure in which a conductive oxide is stacked over tungsten, a two-layer structure in which tungsten is stacked over tantalum nitride, a two-layer structure in which tungsten is stacked over a conductive oxide, a two-layer structure in which tungsten is stacked over titanium nitride, or the like can be used. Alternatively, a three-layer structure in which titanium nitride is stacked over tantalum nitride and tungsten is stacked over the titanium nitride; a three-layer structure in which aluminum is stacked over titanium and titanium is stacked over the aluminum; a three-layer structure in which tungsten is stacked over titanium nitride and a conductive oxide is stacked over the tungsten; a three-layer structure in which tungsten is stacked over a conductive oxide, and a conductive oxide is stacked over the tungsten; or the like can be used. Alternatively, a four-layer structure in which tantalum nitride is stacked over tantalum, titanium nitride is stacked over the tantalum nitride, and tungsten is stacked over the titanium nitride; a four-layer structure in which tantalum is stacked over tantalum nitride, titanium nitride is stacked over the tantalum, and tungsten is stacked over the titanium nitride; a four-layer structure in which titanium nitride is stacked over tantalum nitride, tungsten is stacked over the titanium nitride, and a conductive oxide is stacked over the tungsten; or the like can be used. Alternatively, a five-layer structure in which titanium nitride is stacked over titanium, aluminum is stacked over the titanium nitride, titanium is stacked over the aluminum, and titanium nitride is stacked over the titanium can be employed, for example.

### Semiconductor Layer

As the semiconductor 201 in the semiconductor device described in this embodiment, any of the semiconductors described below can be used as appropriate.

The semiconductor 201 preferably includes a metal oxide exhibiting semiconductor characteristics (an oxide semiconductor).

Indium oxide is preferably used as the metal oxide which can be used for the semiconductor 201. For indium oxide used for the semiconductor 201, the description in Embodiment 3 can be referred to.

The metal oxide which can be used for the semiconductor 201 preferably contains at least indium (In) or zinc (Zn). The metal oxide preferably includes two or three elements selected from In, an element M, and Zn. The element M is a metal element or metalloid element that has a high bonding energy with oxygen, such as a metal element or metalloid element whose bonding energy with oxygen is higher than that of In, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more of the above elements, particularly preferably one or more selected from aluminum, gallium, tin, and yttrium, and further preferably gallium. Hereinafter, a metal oxide containing In, M, and Zn is referred to as In—M—Zn oxide in some cases.

As the metal oxide, it is possible to use zinc oxide, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), or indium gallium aluminum zinc oxide (In—Ga—Al—Zn oxide, also referred to as IGAZO or IAGZO), for example. Alternatively, indium tungsten oxide (In—W oxide, also referred to as IWO) or the like can be used. Alternatively, indium tin oxide containing silicon, gallium tin oxide (Ga—Sn oxide), aluminum tin oxide (Al—Sn oxide), or the like can be used.

When the indium content percentage in the metal oxide is increased, the transistor can have a high on-state current and excellent frequency characteristics.

Specifically, an In-An oxide having an atomic ratio of In:Zn=1:1 or in the neighborhood thereof, an atomic ratio of In:Zn=2:1 or in the neighborhood thereof, or an atomic ratio of In:Zn=4:1 or in the neighborhood thereof can be employed as the composition. In this specification and the like, a composition in the neighborhood includes ±30 % of an intended atomic ratio. In addition, the In—Zn oxide may contain a slight amount of the element M. Examples include an atomic ratio of In:Sn:Zn=4:0.1:1 and a composition in the neighborhood thereof.

When the metal oxide is an In—M—Zn oxide, the proportion of the number of In atoms is preferably higher than or equal to that of the number of M atoms in the In—M—Zn oxide. Examples of the atomic ratio of the metal elements of such In—M—Zn oxide include In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, and a composition in the neighborhood thereof. By increasing the proportion of the number of In atoms in the metal oxide, the on-state current, field-effect mobility, or the like of the transistor can be improved.

The proportion of the number of In atoms may also be lower than that of the number of element M atoms in the In—M—Zn oxide. Examples of the atomic ratio of the metal elements of such In—M—Zn oxide include In:M:Zn=1:3:2, In:M:Zn=1:3:3, and In:M:Zn=1:3:4 and a composition in the neighborhood of any of the above atomic ratios. By increasing the proportion of the number of element M atoms in the metal oxide, generation of oxygen vacancies can be inhibited.

In this specification and the like, the content of a certain metal element in a metal oxide refers to the proportion of the number of atoms of the metal element to the total number of metal element atoms contained in the metal oxide. For example, in the case where a metal oxide contains a metal element X, a metal element Y, and a metal element Z whose atomic numbers are respectively represented by A_{X}, A_{Y}, and A_{Z}, the content of the metal element X can be represented by A_{X}/(A_{X}+A_{Y}+A_{Z}). Moreover, in the case where the atomic ratio between the metal element X, the metal element Y, and the metal element Z contained in the metal oxide is represented by B_{X}:B_{Y}:B_{Z}, the content of the metal element X can be represented by B_{X}/(B_{X}+B_{Y}+B_{Z}).

The semiconductor 201 may have a stacked-layer structure including two or more metal oxide layers. The two or more metal oxides included in the semiconductor 201 may have the same composition or different compositions. For the formation of two or more metal oxides included in the semiconductor 201, the same film formation method or different film formation methods may be used. For example, a two-layer structure may be employed in which a metal oxide deposited by an ALD method is formed over a metal oxide deposited by a sputtering method. Furthermore, a three-layer structure may be employed in which a metal oxide deposited by a sputtering method is further formed over the metal oxide deposited by an ALD method. The use of an ALD method can form a metal oxide layer with a composition that continuously changes in the thickness direction. Furthermore, the use of an ALD method can form a metal oxide layer whose composition and deposition conditions are continuously changed in the thickness direction. This not only increases the range of choices for design without need for use of a film with a predetermined composition but also prevents generation of an interface state or the like between two layers with different compositions; thus, the electrical characteristics and reliability can be improved.

For example, in the case where the semiconductor 201 has a three-layer structure, the second layer preferably includes a material having higher mobility or lower conductivity than the first and third layers. Thus, the second layer mainly serves as a current path, so that interface scattering between the gate insulating layer and the semiconductor 201 is inhibited and a highly reliable transistor can be achieved.

It is preferable to use a metal oxide layer having crystallinity as the semiconductor 201. For example, a metal oxide layer having a single-crystal structure, a c-axis aligned crystalline (CAAC) structure, a polycrystalline structure, a microcrystal structure, a nano-crystalline (nc) structure, or the like can be used. By using a metal oxide layer having crystallinity as the semiconductor 201, the density of defect states in the semiconductor 201 can be reduced, which enables the semiconductor device to have high reliability.

When oxygen vacancies (V_{O}) and impurities are in a channel formation region of a metal oxide in an OS transistor, electrical characteristics of the OS transistor easily vary and the reliability thereof might worsen. In some cases, a defect that is an oxygen vacancy into which hydrogen enters (hereinafter, sometimes referred to as V_{O}H) is formed and an electron functioning as a carrier is generated. Thus, if the channel formation region of the metal oxide includes oxygen vacancies, the OS transistor tends to be normally on. Therefore, the oxygen vacancies and the impurities are preferably reduced as much as possible in the channel formation region in the metal oxide. In other words, the metal oxide preferably includes an i-type (intrinsic) or substantially i-type channel formation region with a low carrier concentration. In addition, in order to reduce the impurity concentration in the metal oxide, the impurity concentration in an adjacent film is also preferably reduced. Examples of impurities include hydrogen, carbon, and nitrogen.

When an oxide semiconductor with sufficiently reduced impurities is used for a channel formation region of a transistor, the transistor can have stable electrical characteristics.

The band gap of a metal oxide functioning as a semiconductor is preferably greater than or equal to 2.0 eV, further preferably greater than or equal to 2.5 eV. The use of a metal oxide having a wide band gap for the oxide semiconductor layer can reduce the off-state current of the transistor. Since the OS transistor has a low off-state current, the power consumption of the semiconductor device can be sufficiently reduced. In addition, the OS transistor has high frequency characteristics, which enables the semiconductor device to operate at high speed.

As the semiconductor material that can be used for the semiconductor 201, a single-element semiconductor or a compound semiconductor can be used, for example. Examples of the single-element semiconductor include silicon (such as single crystal silicon, polycrystalline silicon, microcrystalline silicon, and amorphous silicon) and germanium. Examples of the compound semiconductor include gallium arsenide and silicon germanium. Examples of the compound semiconductor include an organic semiconductor, a nitride semiconductor, and an oxide semiconductor. These semiconductor materials may contain an impurity as a dopant.

Alternatively, the semiconductor 201 may include a layered material functioning as a semiconductor. The layered material generally refers to a group of materials having a layered crystal structure. Such a layered material has high electrical conductivity in a unit layer, that is, high two-dimensional electrical conductivity. When a material that functions as a semiconductor and has high two-dimensional electrical conductivity is used for a channel formation region, the transistor can have high on-state current.

Examples of the layered material include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

There is no particular limitation on the crystallinity of the semiconductor material used for the semiconductor 201, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case degradation of the transistor characteristics can be inhibited.

### Insulator

The insulators 161, 162, 163, 164, 165, 166, 167, 170, 171, 172, 173, 174, 175, 176, 261, 262, 263, 264, 265, 102, and 202 of the semiconductor device described in this embodiment can use any of the following insulators as appropriate. Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, a problem such as generation of leakage current may arise because of a thinner gate insulating film. When a high-dielectric-constant (high-k) insulator is used for the gate insulating film, the voltage at the time of operation of the transistor can be reduced while the physical thickness is maintained. By contrast, when an insulator having a low dielectric constant is used for the insulating layer functioning as an interlayer film, the parasitic capacitance generated between wirings can be reduced. Thus, a material is preferably selected depending on the function of an insulator.

Examples of an insulator having a high dielectric constant (high-k) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium. In addition, an insulating film (also referred to as ZAZ) in which zirconium oxide, aluminum oxide, and zirconium oxide are stacked in this order can be used. An insulating film (also referred to as ZAZA) in which zirconium oxide, aluminum oxide, zirconium oxide, and aluminum oxide are stacked in this order can be used, for example.

Examples of an insulator having a lower dielectric constant than a high-k material include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

Examples of an insulator having high dielectric strength include silicon oxide, silicon oxynitride, silicon nitride oxide, and silicon nitride.

Examples of an insulator that inhibits leakage current include silicon oxide and silicon oxynitride.

A transistor including a metal oxide can have stable electrical characteristics when surrounded by an insulator having a function of inhibiting passage of oxygen and impurities such as hydrogen. The insulator having a function of inhibiting passage of oxygen and impurities such as hydrogen can have, for example, a single-layer structure or a stacked-layer structure of an insulator(s) including one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum. Specifically, an oxide such as aluminum oxide, magnesium oxide, gallium oxide, germanium oxide, yttrium oxide, zirconium oxide, lanthanum oxide, neodymium oxide, hafnium oxide, and tantalum oxide and a nitride such as aluminum nitride, silicon nitride oxide, and silicon nitride can be given as examples.

An insulator in contact with an oxide semiconductor layer, such as a gate insulating film, or an insulator provided in the vicinity of the oxide semiconductor layer preferably includes a region containing oxygen (hereinafter, sometimes referred to as excess oxygen) that is released by heating. For example, when an insulator including a region containing excess oxygen releases oxygen and is positioned in contact with an oxide semiconductor or in the vicinity of the oxide semiconductor, oxygen vacancies in the oxide semiconductor can be reduced. Examples of a material for an insulator in which a region containing excess oxygen is easily formed include silicon oxide, silicon oxynitride, and porous silicon oxide.

For an insulating layer provided in contact with or in the vicinity of the metal oxide that exhibits semiconductor characteristics and is used for the channel or the like of the transistor, an insulator having a function of capturing or fixing hydrogen or an insulator having a barrier property against hydrogen is preferably used. Diffusion of hydrogen into the metal oxide can be inhibited.

Examples of the insulator having a function of capturing or fixing hydrogen include a hafnium oxide, a hafnium silicate, and an aluminum oxide.

A function of capturing or fixing a substance Q can also be referred to as a property that does not easily allow diffusion of the substance Q. In this specification and the like, the barrier property refers to a property that does not easily allow diffusion of the substance Q (also referred to as a property that does not easily allow passage of the substance Q, a property with low permeability of the substance Q, or a function of inhibiting diffusion of the substance Q). Thus, a function of capturing or fixing the substance Q can be rephrased as a barrier property. Note that hydrogen described as the substance Q refers to at least one of a hydrogen atom, a hydrogen molecule, and a substance bonded to hydrogen, such as a water molecule or OH⁻, for example. Unless otherwise specified, an impurity described as the substance Q refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), a copper atom, and the like. Oxygen described as the substance Q refers to, for example, at least one of an oxygen atom, an oxygen molecule, and the like.

Examples of the insulator having a barrier property against hydrogen include silicon nitride, hafnium oxide, aluminum oxide, magnesium oxide, gallium oxide, and silicon nitride oxide.

Examples of an insulator having a barrier property against oxygen include an oxide containing one or both of aluminum and hafnium, magnesium oxide, gallium oxide, gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate).

A material that shows ferroelectricity may be used for an insulator included in the semiconductor device. Examples of the material having ferroelectricity include metal oxides such as hafnium oxide, zirconium oxide, and hafnium zirconium oxide.

A material exhibiting ferroelectricity can be used for at least part of the gate insulating film of the transistor. Furthermore, a transistor including the gate insulating film can function as a ferroelectric field-effect transistor (FeFET).

### Gate Insulating Film

As the insulator 102 in the semiconductor device described in this embodiment, any of the insulators described below can be used as appropriate. The insulator 102 functions as a gate insulating film of a Si transistor. As the insulator 102, any of the insulators given in <Insulator> above can be appropriately used. The gate insulating film, which is the insulator 102, can have a single-layer structure or a stacked-layer structure including two or more layers. In the case where the gate insulating film has a stacked-layer structure of two or more layers, the gate insulating film is preferably formed using two or more kinds of films. When the gate insulating film of the insulator 102 is formed using two or more kinds of films, the insulator 102 can have a plurality of functions.

The insulator 102 can be one of or a stack of two or more of an insulator having a high dielectric constant, an insulator having high dielectric strength, and an insulator that inhibits leakage current. Moreover, a material exhibiting ferroelectricity can be used for the insulating layer such as the insulator 102.

As a specific example of the insulator 102, a two-layer structure in which a silicon oxide film and a hafnium oxide film are stacked in this order from the semiconductor 101 side is preferably used, and their thicknesses are preferably 1 nm and 1.5 nm from the semiconductor 101 side.

As the insulator 202 in the semiconductor device described in this embodiment, any of the insulators described below can be used as appropriate. The insulator 202 functions as a gate insulating film of an OS transistor. As a gate insulating film such as the insulator 202, any of the insulators given in <Insulator> above can be appropriately used. The gate insulating film such as the insulator 202 can have a single-layer structure or a stacked-layer structure including two or more layers. In the case where the gate insulating film has a stacked-layer structure of two or more layers, the gate insulating film is preferably formed using two or more kinds of films. When the gate insulating film such as the insulator 202 is formed using two or more kinds of films, the insulator 202 and the like can have a plurality of functions.

The insulator 202 can be one of or a stack of two or more of an insulator having a high dielectric constant, an insulator having high dielectric strength, and an insulator that inhibits leakage current. Moreover, a material exhibiting ferroelectricity can be used for the insulating layer such as the insulator 202.

The insulator 202 can have a two-layer structure including a first insulating layer in contact with the semiconductor 201 and a second insulating layer on the side closer to the conductor 203 functioning as a gate electrode. An insulator having a function of capturing or fixing hydrogen can be used for the first insulating layer, and an insulator having a barrier property against hydrogen, an insulator having a function of inhibiting passage of oxygen and impurities such as hydrogen, or an insulator having a barrier property against oxygen can be used for the second insulating layer. Such a structure can reduce the hydrogen concentration in the semiconductor 201 and can reduce diffusion of hydrogen into the semiconductor 201. In addition, diffusion of oxygen to the conductor 203 side can be prevented, so that oxidation of the conductor 203 can be inhibited. Accordingly, the transistor can have high reliability. In the case where the insulator 202 has the two-layer structure, for example, a hafnium oxide film or a hafnium silicate film can be used as the first insulating layer, and a silicon nitride film can be used as the second insulating layer.

Alternatively, an insulator having high dielectric strength or an insulator that inhibits leakage current can be used as the first insulating layer, and an insulator having a function of capturing or fixing hydrogen, an insulator having a barrier property against hydrogen, an insulator having a function of inhibiting passage of oxygen and impurities such as hydrogen, or an insulator having a barrier property against oxygen can be used as the second insulating layer. Such a structure can reduce gate leakage current and can inhibit diffusion of hydrogen into the semiconductor 201. In addition, diffusion of oxygen to the conductor 203 side can be prevented, so that oxidation of the conductor 203 can be inhibited. Accordingly, the transistor can have high reliability. In the case where the insulator 202 has a two-layer structure, for example, a silicon oxide film can be used as the first insulating layer and a hafnium oxide film can be used as the second insulating layer.

Alternatively, the insulator 202 can have a three-layer structure including the first insulating layer, the second insulating layer, and a third insulating layer. At this time, the first insulating layer is in contact with the semiconductor 201, and the first insulating layer, the second insulating layer, and the third insulating layer are arranged in this order from the semiconductor 201 side toward the conductor 203 functioning as the gate electrode. An insulator having high dielectric strength or an insulator that inhibits leakage current can be used as the first insulating layer, an insulator having a function of capturing or fixing hydrogen can be used as the second insulating layer, and an insulator having a barrier property against hydrogen, an insulator having a function of inhibiting passage of oxygen and impurities such as hydrogen, or an insulator having a barrier property against oxygen can be used as the third insulating layer. Such a structure can reduce gate leakage current and can inhibit diffusion of hydrogen into the semiconductor 201. In addition, diffusion of oxygen to the conductor 203 side can be prevented, so that oxidation of the conductor 203 can be inhibited. Accordingly, the transistor can have high reliability. In the case where the insulator 202 has a three-layer structure, for example, a silicon oxide film can be used as the first insulating layer, a hafnium oxide film or a hafnium silicate film can be used as the second insulating layer, and a silicon nitride film can be used as the third insulating layer.

Alternatively, the insulator 202 can have a four-layer structure including the first insulating layer, the second insulating layer, the third insulating layer, and a fourth insulating layer. At this time, the first insulating layer is in contact with the semiconductor 201, and the first insulating layer, the second insulating layer, the third insulating layer, and the fourth insulating layer are arranged in this order from the semiconductor 201 side toward the conductor 203 functioning as the gate electrode. An insulator having a barrier property against oxygen or an insulator having a function of inhibiting passage of oxygen and impurities such as hydrogen can be used as the first insulating layer, an insulator having a function of inhibiting leakage current of an insulator having high dielectric strength can be used as the second insulating layer, an insulator having a function of capturing or fixing hydrogen can be used as the third insulating layer, and an insulator having a barrier property against hydrogen or a function of inhibiting passage of oxygen and impurities such as hydrogen can be used as the fourth insulating layer. With such a structure, release of oxygen from the semiconductor 201 can be inhibited. Furthermore, gate leakage current can be reduced, so that diffusion of hydrogen to the semiconductor 201 can be inhibited. In addition, diffusion of oxygen to the conductor 203 side can be prevented, so that oxidation of the conductor 203 can be inhibited. Accordingly, the transistor can have high reliability. In the case where the insulator 202 has a four-layer structure, for example, an aluminum oxide film can be used as the first insulating layer, a silicon oxide film can be used as the second insulating layer, a hafnium oxide film or a hafnium silicate film can be used as the third insulating layer, and a silicon nitride film can be used as the fourth insulating layer.

The gate insulating film such as the insulator 202 is preferably a thin film. For example, when the insulator 202 has a thickness greater than or equal to 1 nm and less than or equal to 50 nm, greater than or equal to 1 nm and less than or equal to 20 nm, preferably greater than or equal to 3 nm and less than or equal to 10 nm, the subthreshold swing value (also referred to as S value), which is one of transistor characteristics, can be reduced. Note that the S value means the amount of change in gate voltage in a subthreshold region when drain voltage is constant and drain current is changed by one order of magnitude. Note that at least part of the insulator 202 includes a region with the above thickness.

The thickness of each layer included in the insulating layer such as the insulator 202 is preferably greater than or equal to 0.1 nm and less than or equal to 40 nm, preferably greater than or equal to 0.1 nm and less than or equal to 10 nm, further preferably greater than or equal to 0.1 nm and less than or equal to 5 nm, still further preferably greater than or equal to 0.5 nm and less than or equal to 5 nm, yet further preferably greater than or equal to 1 nm and less than 5 nm, yet still further preferably greater than or equal to 1 nm and less than or equal to 3 nm. Note that each layer included in the insulator 202 at least partly includes a region with the above-described thickness.

As a specific example of the insulator 202, a four-layer structure in which an aluminum oxide film, a silicon oxide film, a hafnium oxide film, and a silicon nitride film are stacked in this order from the semiconductor 201 side is preferably employed, and their thicknesses are preferably 1 nm, 2 nm, 2 nm, and 1 nm from the semiconductor 201 side. Alternatively, their thicknesses are preferably 1 nm, 30 nm, 1.5 nm, and 1 nm from the semiconductor 201 side. Alternatively, these thicknesses are preferably 1 nm, 30 nm, 1.5 nm, and 5 nm from the semiconductor 201 side.

As another specific example, a four-layer structure in which a hafnium oxide film, a silicon oxide film, a hafnium oxide film, and a silicon nitride film are stacked in this order from the semiconductor 201 side is preferably employed, and their thicknesses are preferably 1 nm, 2 nm, 2 nm, and 1 nm from the semiconductor 201 side.

As another specific example, a two-layer structure in which a silicon oxide film and a hafnium oxide film are stacked in this order from the semiconductor 201 side is preferably employed, and their thicknesses are preferably 1 nm and 1.5 nm from the semiconductor 201 side.

As another specific example, a three-layer structure in which a silicon oxide film, a hafnium oxide film, and a silicon nitride film are stacked in this order from the semiconductor 201 side is preferably employed, and their thicknesses are preferably 30 nm, 1.5 nm, and 5 nm from the semiconductor 201 side.

### Modification Example 1 of Semiconductor Device

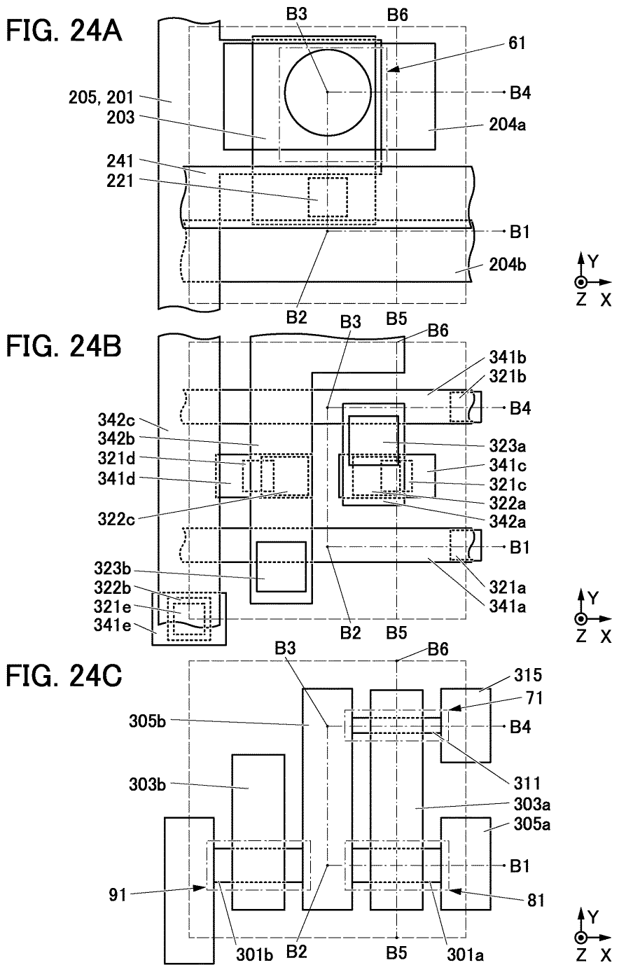

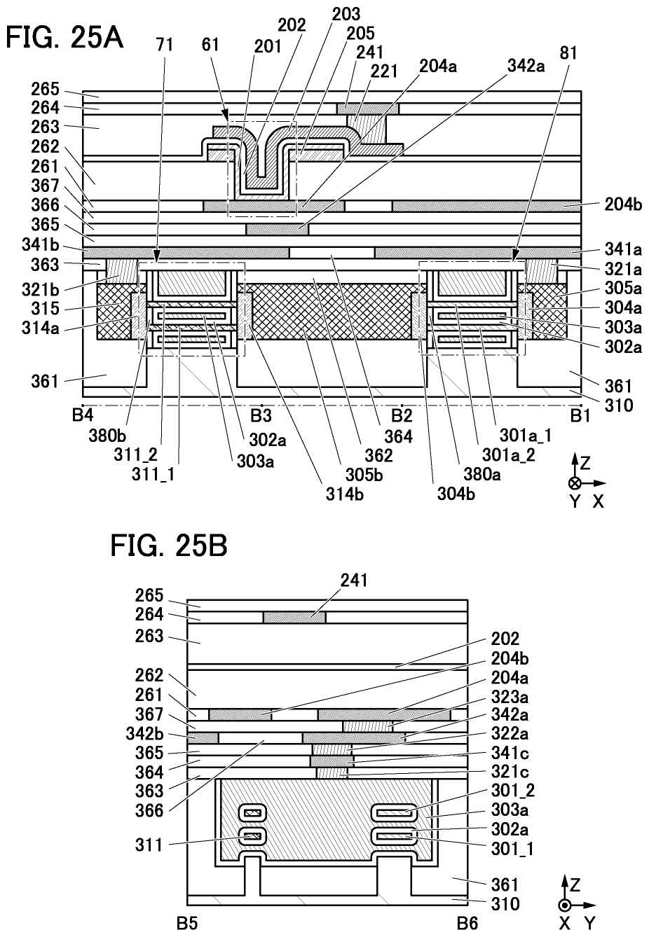

FIGS. 24A to 24C and FIGS. 25A and 25B show a modification example of the memory cell 10 used in the semiconductor device of one embodiment of the present invention. Differences from the description of the memory cell 10 of one embodiment of the present invention in FIGS. 17A to 23 are mainly described below; the description of FIGS. 17A to 23 can be referred to for the similar portions and the description is omitted in some cases.

FIGS. 24A to 25B show examples of schematic top views and schematic cross-sectional views of the structure in FIG. 16C. FIGS. 24A to 24C are each an example of a schematic top view of the memory cell 10. Since the memory cell 10 of one embodiment of the present invention has a multilayer structure, conductor layers and semiconductor layers in different layers are separately shown in FIGS. 24A to 24C. Specifically, FIG. 24C shows a layer on the substrate side, FIG. 24B shows a layer over the layer shown in FIG. 24C, and FIG. 24A shows a layer over the layer shown in FIG. 24B.

A transistor 61 shown in FIGS. 24A and 25A corresponds to the transistor M1 in FIG. 16C. A transistor 71 shown in FIGS. 24C and 25A corresponds to the transistor M2 in FIG. 16C. A transistor 81 shown in FIGS. 24C and 25A corresponds to the transistor M3 in FIG. 16C. A transistor 91 shown in FIG. 24C corresponds to the transistor M4 in FIG. 16C.

FIG. 25A is a schematic cross-sectional view taken along the dashed-dotted line B1-B2-B3-B4 in FIGS. 24A to 24C. FIG. 25B is a schematic cross-sectional view taken along the dashed-dotted line B5-B6 in FIGS. 24A to 24C.

The transistor 81 includes at least a semiconductor 301a (a semiconductor 301a_1 and a semiconductor 301a_2), a conductor 304a, a conductor 304b, an insulator 302a, and a conductor 303a. The conductor 303a is provided to surround a top surface, a bottom surface, and a pair of opposite side surfaces of the semiconductor 301a (the semiconductor 301a_1 and the semiconductor 301a_2). The insulator 302a is provided to be positioned between the conductor 303a and the semiconductor 301a (the semiconductor 301a_1 and the semiconductor 301a_2). The conductor 304a includes a region in contact with the semiconductor 301a. Specifically, the conductor 304a includes a region in contact with the semiconductor 301a_1 and a region in contact with the semiconductor 301a_2. The conductor 304b includes a region in contact with the semiconductor 301a. Specifically, the conductor 304b includes a region in contact with the semiconductor 301a_1 and a region in contact with the semiconductor 301a_2.

A conductor 305a includes a region in contact with the conductor 304a. A conductor 305b includes a region in contact with the conductor 304b.

Part or the whole of the semiconductor 301a (the semiconductor 301a_1 and the semiconductor 301a_2) can function as a channel formation region of the transistor 81. Part or the whole of the conductor 304a can function as one of a source region and a drain region of the transistor 81. Part or the whole of the conductor 304b can function as the other of the source region and the drain region of the transistor 81. Part or the whole of the insulator 302a can function as a gate insulating film of the transistor 81. Part or the whole of the conductor 303a can function as a gate electrode of the transistor 81.

The transistor 71 includes at least a semiconductor 311 (a semiconductor 311_1 and a semiconductor 311_2), a conductor 314a, a conductor 314b, the insulator 302a, and the conductor 303a. The conductor 303a is provided to surround a top surface, a bottom surface, and a pair of opposite side surfaces of the semiconductor 311 (the semiconductor 311_1 and the semiconductor 311_2). The insulator 302a is provided to be positioned between the conductor 303a and the semiconductor 311 (the semiconductor 311_1 and the semiconductor 311_2). The conductor 314a includes a region in contact with the semiconductor 311. Specifically, the conductor 314a includes a region in contact with the semiconductor 311_1 and a region in contact with the semiconductor 311_2. The conductor 314b includes a region in contact with the semiconductor 311. Specifically, the conductor 314b includes a region in contact with the semiconductor 311_1 and a region in contact with the semiconductor 311_2.

A conductor 315 includes a region in contact with the conductor 314a. The conductor 305b includes a region in contact with the conductor 314b.

Part or the whole of the semiconductor 311 (the semiconductor 311_1 and the semiconductor 311_2) can function as a channel formation region of the transistor 71. Part or the whole of the conductor 314b can function as one of a source region and a drain region of the transistor 71. Part or the whole of the conductor 314a can function as the other of the source region and the drain region of the transistor 71. Part or the whole of the insulator 302a can function as a gate insulating film of the transistor 71. Part or the whole of the conductor 303a can function as a gate electrode of the transistor 71.

The transistor 91 has a structure similar to that of the transistor 81. As shown in FIG. 24C, the transistor 91 includes at least a conductor 303b and a semiconductor 301b. The conductor 305b is in contact with one of a source and a drain of the transistor 91. The conductor 315 is in contact with the other of the source and the drain of the transistor 91.

For the transistor 61, the description of the structure of the transistor 60 can be referred to.

An insulator 380a is provided between the conductor 304b and the insulator 302a and between the conductor 304a and the insulator 302a. An insulator 380b is provided between the conductor 314b and the insulator 302a and between the conductor 314a and the insulator 302a. With the insulator 380, the conductor 304 can be apart from the conductor 303, and the parasitic capacitance generated between the conductor 304 and the conductor 303 can be reduced. In addition, with the insulator 380, the conductor 314 can be apart from the conductor 303, and the parasitic capacitance generated between the conductor 314 and the conductor 303 can be reduced.

In the semiconductor device of one embodiment of the present invention, the transistor 61 (an OS transistor) can be formed to overlap with any one or more of the transistor 71 (a p-type Si transistor), the transistor 81 (an n-type Si transistor), and the transistor 91 (an n-type Si transistor). Thus, the memory cell 10 that occupies a small area can be formed. In addition, a memory device in which memory cells are arranged at high density can be achieved.

For the semiconductor 301, the description of the semiconductor 101 can be referred to. For the semiconductor 311, the description of the semiconductor 111 can be referred to. For the insulator 302, the description of the insulator 102 can be referred to. For the conductor 303, the description of the conductor 103 can be referred to. For the conductors 304 and 314, the descriptions of the conductors 104 and 114 can be referred to. For the conductors 305 and 315, the descriptions of the conductors 105 and 115 can be referred to.

The conductor 303a is connected to a conductor 204a through a conductor 321c, a conductor 341c, a conductor 322a, a conductor 342a, and a conductor 323a. The conductor 203 is connected to the conductor 241 through the conductor 221.

The conductor 241 can function as part or the whole of the wiring NL11 in FIG. 16C. The conductor 205 can function as part or the whole of the wiring NL12 in FIG. 16C. As shown in FIG. 24A, the conductor 241 is provided to extend in the X direction. The conductor 205 is provided to extend in the Y direction.

The conductor 303b is connected to a conductor 204b through a conductor 321d, a conductor 341d, a conductor 322c, a conductor 342b, and a conductor 323b. The conductor 204b can function as part or the whole of the wiring NL13 in FIG. 16C. As shown in FIG. 24A, the conductor 204b is provided to extend in the X direction.

The conductor 305a is connected to a conductor 341a through a conductor 321a. The conductor 321a is provided in an opening portion formed in an insulator 362 and an insulator 363. The conductor 321a includes a region in contact with part of the top surface of the conductor 305a. The conductor 315 is connected to a conductor 341b through a conductor 321b. The conductor 321b is provided in an opening portion formed in the insulator 362 and the insulator 363. The conductor 321b includes a region in contact with part of the top surface of the conductor 315.

The conductor 341a can function as part or the whole of the wiring NL16 in FIG. 16C. The conductor 341b can function as part or the whole of the wiring NL15 in FIG. 16C. As shown in FIG. 24B, the conductor 341 (the conductor 341a and the conductor 341b) is provided to extend in the X direction.

As shown in FIGS. 24B and 24C, the conductor 315 connected to the other of the source and the drain of the transistor 91 is connected to a conductor 342c through a conductor 321e, a conductor 341e, and a conductor 322b.

The conductor 342c can function as part or the whole of the wiring NL14 in FIG. 16C. As shown in FIG. 24B, the conductor 342c is provided to extend in the Y direction.

For a substrate 310, the description of the substrate 110 can be referred to.

The conductors 341, 342, and 241 can function as wirings. The conductors 321, 322, 323, and 221 function as plugs, electrodes, or wirings. The conductors 305, 315, and 303 can function as electrodes or wirings. For these conductors, the above description of <Conductor>in [Materials] can be referred to.

The following insulators can also function as interlayer insulating films: an insulator 361, the insulator 362, the insulator 363, an insulator 364, an insulator 365, an insulator 366, an insulator 367, the insulator 261, the insulator 262, the insulator 263, the insulator 264, and the insulator 265. For these insulators, the above description of <Insulator>in [Materials] can be referred to.

### Modification Example 2 of Semiconductor Device

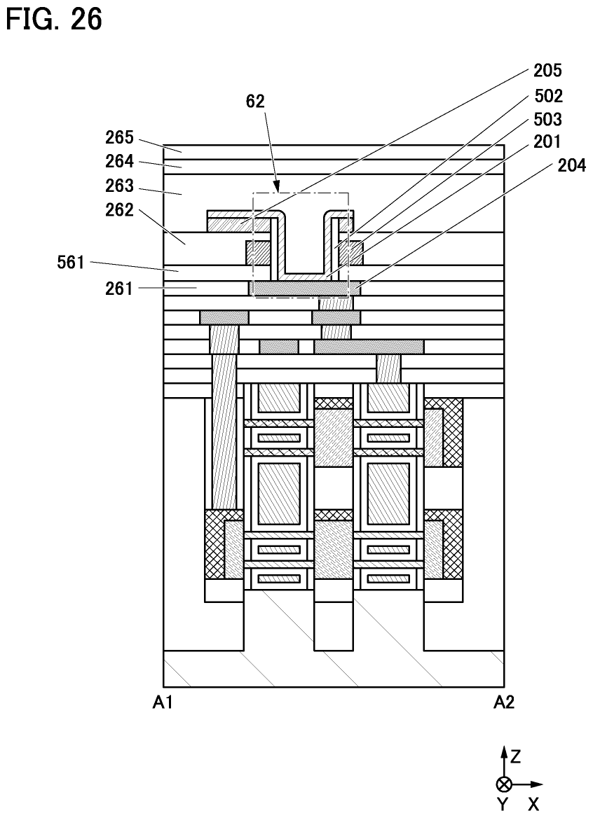

FIG. 26 shows a modification example of the memory cell 10 used in the semiconductor device of one embodiment of the present invention. The semiconductor device in FIG. 26 is an example in which the structure of the transistor 60 in the semiconductor device in FIG. 18 is changed and a transistor 62 is used. The transistor 62 corresponds to the transistor M1 in FIG. 16B.

The transistor 62 is an example in which the insulator 202 and the conductor 203 in the transistor 60 are changed into an insulator 502 and a conductor 503, respectively. The conductor 503 is positioned above the conductor 204 and is positioned below the conductor 205. An insulator 561 provided above the conductor 204 is positioned between the conductor 503 and the conductor 204. The insulator 262 provided below the conductor 205 is positioned between the conductor 503 and the conductor 205.

The conductor 205, the insulator 262, the conductor 503, and the insulator 561 have an opening portion reaching the conductor 204. The insulator 502 is positioned in the opening portion and includes a region in contact with the side surface of the conductor 503, a region in contact with the side surface of the insulator 561, and a region in contact with the side surface of the insulator 262.

The semiconductor 201 includes a region in contact with the top surface of the conductor 205, a region in contact with the insulator 502 in the opening portion, and a region in contact with the top surface of the conductor 204.

Part or the whole of the conductor 503 can function as a gate electrode of the transistor 62. Part or the whole of the insulator 502 can function as a gate insulating film of the transistor 62.

For the conductor 503, the description of the conductor 203 can be referred to. For the insulator 502, the description of the insulator 202 can be referred to.

### Modification Example 3 of Semiconductor Device

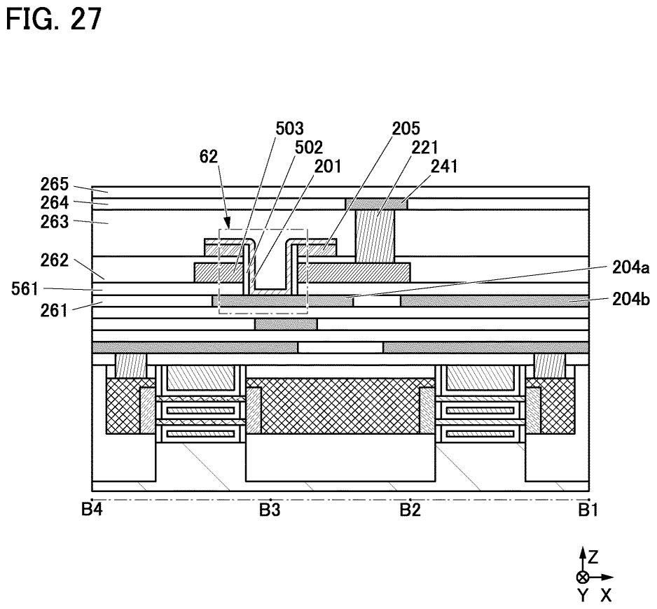

FIG. 27 shows a modification example of the memory cell 10 used in the semiconductor device of one embodiment of the present invention. The semiconductor device in FIG. 27 is an example in which the structure of the transistor 61 in the semiconductor device in FIG. 25A is changed and the transistor 62 is used. The transistor 62 corresponds to the transistor M1 in FIG. 16C.

At least part of this embodiment can be implemented as appropriate in combination with any of the other embodiments described in this specification. In this specification, in the case where a plurality of structure examples or modification examples are shown in one embodiment, the structure examples and modification examples can be combined as appropriate.

### Embodiment 3

In this embodiment, an indium oxide film that can be used for the semiconductor layer of the transistor included in the memory cell 10 of one embodiment of the present invention will be described.

In this specification and the like, indium oxide including at least a crystal part or a crystal region in a film is referred to as crystal indium oxide (crystal IO) or crystalline indium oxide (crystalline IO). Examples of crystal IO or crystalline IO include single crystal indium oxide, polycrystal indium oxide, and microcrystal indium oxide.

Indium oxide is a semiconductor material having physical properties completely different from those of an oxide semiconductor such as In—Ga-Zn oxide (hereinafter, also referred to as IGZO) or zinc oxide.

The dependence of the Hall mobility on the carrier concentration of indium oxide, silicon, and IGZO will be described.

IGZO has a tendency in which the Hall mobility is higher as the carrier concentration is higher. By contrast, single crystal indium oxide has a tendency in which the Hall mobility is higher as the carrier concentration is lower. This tendency is similar to that of silicon; as the concentration of a dopant (impurity) in a material is lower, impurity scattering is inhibited more and thus the Hall mobility is higher. That is, single crystal indium oxide having higher purity and being more intrinsic has higher Hall mobility. Consequently, the physical properties of single crystal indium oxide are different from those of IGZO and similar to those of silicon. Note that the tendency of non-single-crystal (e.g., polycrystal) indium oxide is sometimes different from that of single crystal indium oxide.

A carrier concentration range suitable for a channel formation region of a transistor is a range including a carrier concentration of 1×10¹⁵cm⁻³, e.g., a range with a carrier concentration higher than or equal to 1×10¹⁴ cm⁻³ and lower than or equal to 1×10¹⁸cm⁻³. The adequately lowered carrier concentration will increase the Hall mobility to approximately 270 cm²/(V×s).

Indium oxide can include an element that reduces the carrier concentration. Examples of the element that reduces the carrier concentration include magnesium, calcium, zinc, cadmium, and copper. When indium is replaced with any of these elements, the carrier concentration can be reduced. Other examples include nitrogen, phosphorus, arsenic, and antimony. When oxygen is replaced with any of these elements, the carrier concentration can be reduced.

The element that reduces the carrier concentration can also be referred to as an element that imparts p-type conductivity. When the element that reduces the carrier concentration is added to an indium oxide film, the indium oxide film is likely to be i-type or substantially i-type in some cases. In that case, the concentration of the element that reduces the carrier concentration in the indium oxide film is preferably higher than or equal to 1×10¹⁶ atoms/cm³ and lower than or equal to 8×10²⁰atoms/cm³, further preferably higher than or equal to 1×10¹⁶ atoms/cm³ and lower than or equal to 4×10²⁰atoms/cm³, still further preferably higher than or equal to 1×10¹⁶ atoms/cm³ and lower than or equal to 8×10¹⁹atoms/cm³, yet still further preferably higher than or equal to 1×10¹⁶ atoms/cm³ and lower than or equal to 5×10¹⁹atoms/cm³. With such a concentration, the carrier concentration can be reduced while the crystal structure of indium oxide is maintained.

By contrast, an increase in carrier concentration can reduce electrical resistance. A carrier concentration range suitable for a source region and a drain region of a transistor, a resistor, or a transparent conductive film is, for example, a range including a carrier concentration of 1×10²⁰cm⁻³, e.g., a range with a carrier concentration higher than or equal to 1×10¹⁹ cm⁻³ and lower than or equal to 1×10²²cm⁻³. The adequately increased carrier concentration will decrease the resistivity to 1×10⁻⁴ Ω×cm or lower.

Indium oxide can include an element that increases the carrier concentration. For example, the same element as a source electrode and a drain electrode of a transistor is preferably included. Examples of the element that increases the carrier concentration include titanium, zirconium, hafnium, tantalum, tungsten, molybdenum, tin, silicon, and boron. It is particularly preferable that an oxide of the element have conductivity or semiconductor properties.

The element that increases the carrier concentration can also be referred to as an element that imparts n-type conductivity. The concentration of the element that increases the carrier concentration in the indium oxide film is preferably higher than or equal to 1×10¹⁶ atoms/cm³ and lower than or equal to 8×10²⁰atoms/cm³, further preferably higher than or equal to 1×10¹⁶ atoms/cm³ and lower than or equal to 4×10²⁰atoms/cm³, still further preferably higher than or equal to 1×10¹⁶ atoms/cm³ and lower than or equal to 8×10¹⁹atoms/cm³, yet still further preferably higher than or equal to 1×10¹⁶ atoms/cm³ and lower than or equal to 5×10¹⁹atoms/cm³. With such a concentration, the carrier concentration can be increased while the crystal structure of indium oxide is maintained. Note that antimony also functions as an element that increases the carrier concentration in some cases.

Since indium oxide is an oxide whose valence electron can be controlled, the threshold voltage of a transistor using a semiconductor layer containing indium oxide can be controlled. In this manner, the region with a low carrier concentration and the region with a high carrier concentration of indium oxide can be used as a channel formation region and source and drain regions, respectively, of a transistor. Thus, what is called an n-i-n junction (a junction between an n-type region, an i-type region, and an n-type region) can be formed. Although valence electron control in a transistor containing silicon is generally known, valence electron control in a transistor containing indium oxide is a novel technical idea that cannot be conceived usually. With the use of this technical idea, a transistor that has high mobility, has a low off-state current, can be normally off, and has high reliability can be achieved.

An indium oxide film preferably has crystallinity. In particular, the indium oxide film is preferably a polycrystal film, further preferably a single crystal film. A single crystal film does not have a crystal grain boundary (also referred to as a grain boundary). The use of a single crystal film can inhibit carrier scattering or the like at the crystal grain boundary, thereby achieving a transistor having high field-effect mobility. In addition, the use of a single crystal film produces an excellent effect of reducing a variation in transistor characteristics caused by the crystal grain boundary.

A polycrystal film is preferable because it can reduce carrier scattering as compared with a microcrystal film or an amorphous film and enables a transistor to have high field-effect mobility. In the case of using a polycrystal film, it is preferable to use a film that has as large a crystal grain size as possible and few crystal grain boundaries. In the case where the crystal grain boundary is neither included nor observed in a channel formation region of a transistor including a polycrystal film, the channel formation region is positioned in a single crystal region included in the polycrystal film and thus the transistor can be regarded as a transistor including a single crystal film.

The crystallinity of indium oxide can be analyzed with an X-ray diffraction (XRD) pattern, a transmission electron microscope (TEM) image, or an electron diffraction (ED) pattern, for example. Alternatively, two or more of these methods may be combined for the analysis.

In this specification and the like, a semiconductor layer where no crystal grain boundary is observed in a channel formation region, a semiconductor layer where a channel formation region is included in one crystal grain, or a semiconductor layer where the directions of crystal axes of at least two regions in a channel formation region are the same can be regarded as a single crystal film.

A channel formation region refers to a region of a semiconductor layer that overlaps with (or faces) a gate electrode with a gate insulating layer therebetween and is positioned between a region in contact with a source electrode and a region in contact with a drain electrode. A crystal grain, a crystal grain boundary, a crystal axis, a crystal orientation, or the like in a channel formation region can be confirmed in observation of a cross section including a semiconductor layer, a source electrode, and a drain electrode.

Impurities in the indium oxide film can function as a carrier scattering source and thus can cause a reduction in field-effect mobility and inhibit crystal growth. Examples of the impurities for the indium oxide film include boron and silicon. The concentrations of the impurities in the indium oxide film in the channel formation region are preferably as low as possible. For example, the concentrations of the impurity elements are each lower than or equal to 0.1 %, preferably lower than or equal to 0.01 % (100 ppm). Note that carbon, hydrogen, and the like are elements that would be contained in a film formation gas or a precursor in film formation, and the amounts of these elements remaining in the indium oxide film might be larger than those of the impurities.

The indium oxide film may contain an element that can form a trivalent cation like indium as long as the cubic crystal structure (bixbyite structure) is maintained. Examples of the element include Group 13 elements such as gallium and aluminum and Group 3 elements in the periodic table. These elements are each more strongly bonded to oxygen than indium is; thus, by adding these elements to the indium oxide film, formation of oxygen vacancies (V_{O}) in the indium oxide film can be inhibited. Since these elements exist mainly as trivalent cations in oxides, the carrier concentration of indium oxide film can be kept low. In this way, the threshold voltage of the transistor can be shifted in the positive direction. In addition, the transistor can be normally-off. Thus, a transistor having favorable electrical characteristics can be provided.

The concentration of the above elements in the indium oxide film is preferably higher than or equal to 1×10¹⁶ atoms/cm³ and lower than or equal to 8×10²⁰atoms/cm³, further preferably higher than or equal to 1×10¹⁶ atoms/cm³ and lower than or equal to 4×10²⁰ atoms/cm³, still further preferably higher than or equal to 1×10¹⁶ atoms/cm³ and lower than or equal to 8×10¹⁹atoms/cm³, yet still further preferably higher than or equal to 1×10¹⁶ atoms/cm³ and lower than or equal to 5×10¹⁹atoms/cm³.

Note that the element imparting n-type conductivity, the element imparting p-type conductivity, and the element that can be a trivalent cation can be added to the indium oxide film by an ion doping method, an ion implantation method, a thermal diffusion method, or the like. Alternatively, the element imparting n-type conductivity, the element imparting p-type conductivity, and the element that can form a trivalent cation can each be added to a sputtering target, a deposition gas, a precursor for deposition of an ALD film, or the like for depositing an indium oxide film. Alternatively, the element imparting n-type conductivity, the element imparting p-type conductivity, and the element that can be a trivalent cation can each be autodoped from the chamber where the indium oxide film is formed. Note that autodoping means that an element contained in a member or the like of a depositing chamber is automatically added to an indium oxide film at the time of deposition.

A transistor including the above indium oxide film can have a field-effect mobility higher than or equal to 50 cm²/(V×s), preferably higher than or equal to 100 cm²/(V×s), further preferably higher than or equal to 150 cm²/(V×s), still further preferably higher than or equal to 200 cm²/(V×s), yet still further preferably higher than or equal to 250 cm²/(V×s).

One feature of an indium oxide film is to have a higher property of transmitting (diffusing) oxygen than an IGZO film. For example, oxygen diffusing in an indium oxide film is transmitted through the indium oxide film and released as an oxygen molecule. When reacting with hydrogen contained in the film, oxygen is released as a water molecule in some cases. In the case where the film includes oxygen vacancies, the oxygen vacancies are filled with diffusing oxygen atoms. Since oxygen easily diffuses in the indium oxide film, oxygen vacancies in the indium oxide film are filled with oxygen more easily than those in an IGZO film.

As described above, the oxygen vacancies in the indium oxide film are reduced more easily than those in the IGZO film; thus, a transistor including such an indium oxide film can have extremely high reliability.

Hydrogen diffuses in the indium oxide film. Hydrogen diffusing into the indium oxide film from the outside is transmitted through the indium oxide film and is released as a hydrogen molecule. When reacting with oxygen contained in the film, hydrogen is released as a water molecule.

Indium oxide has features of a small effective mass of electrons and a large effective mass of holes. In addition, the effective mass of electrons in indium oxide hardly depends on the crystal orientation. Thus, a transistor containing indium oxide having crystallinity can have high field-effect mobility and high frequency characteristics (also referred to as f characteristics). A large effective mass of holes allows a transistor to have an extremely low off-state current. For example, the off-state current per micrometer of channel width of a vertical transistor including an indium oxide film can be lower than or equal to 1 fA (1×10⁻¹⁵ A) or lower than or equal to 1 aA (1×10⁻¹⁸ A) at 125 ° C, and can be lower than or equal to 1 aA (1×10⁻¹⁸ A) or lower than or equal to 1 zA (1×10⁻²¹ A) at room temperature (25 ° C). Since indium oxide has a smaller effective mass of electrons and a larger effective mass of holes than silicon, a transistor containing indium oxide can have higher field-effect mobility and lower off-state current than a Si transistor.

A seed layer is preferably provided in contact with at least part of the indium oxide film having crystallinity. A material of the seed layer is preferably selected such that the difference in a lattice constant (also referred to as lattice mismatch) between the crystal included in indium oxide and the crystal included in the material is small. In that case, the crystallinity of the indium oxide film can be improved. As a layer in contact with at least part of the indium oxide film having crystallinity, a substrate (e.g., a single crystal substrate) may be used.

One of methods for evaluating the degree of a lattice mismatch is a method using a value of a lattice mismatch degree described below. A lattice mismatch degree Δa [%] of a crystal included in a film to be formed (here, the indium oxide film) with respect to the crystal included in the seed layer is calculated by the formula: Δa=((L₁−L₂)/L₂)×100. Here, L₁ is the lattice constant or the length of the unit lattice vector of the crystal included in the film to be formed, and L₂ is the lattice constant or the length of the unit lattice vector of the crystal included in the seed layer.

The absolute value of the lattice mismatch degree Δa between the seed layer and the indium oxide film is preferably as small as possible, most preferably 0. For example, Δa can be greater than or equal to −5 % and less than or equal to 5 %, preferably greater than or equal to −4 % and less than or equal to 4 %, further preferably greater than or equal to −3 % and less than or equal to 3 %, still further preferably greater than or equal to −2 % and less than or equal to 2 %.

An indium oxide crystal has a cubic crystal structure (a bixbyite structure). For example, an yttria-stabilized zirconia (YSZ) crystal can have a cubic crystal structure (a fluorite crystal structure). The lattice mismatch degree of an indium oxide crystal with respect to an YSZ crystal having the cubic crystal structure is within the range of −2 % to 2 % , which enables epitaxial growth of a single crystal film of indium oxide over the YSZ substrate.

The crystal structures of the seed layer and the indium oxide film do not necessarily have the same crystal system or crystal orientation in some cases. For example, a film including a crystal with a hexagonal crystal structure or a trigonal crystal structure can be provided below an indium oxide film including a crystal with a cubic crystal structure. For example, when the crystal orientation of a seed layer surface is set to [001] and the crystal orientation of a bottom surface of the indium oxide film is set to [111], the necessary condition for crystal orientation in epitaxial growth can be satisfied. Examples of a hexagonal or trigonal crystal structure include a wurtzite structure, a YbFe₂O₄-type structure, a Yb₂Fe₃O₇-type structure, and variations of these structures. An example of a crystal having a YbFe₂O₄-type structure or a Yb₂Fe₃O₇-type structure is IGZO.

At least part of this embodiment can be implemented as appropriate in combination with any of the other embodiments described in this specification.

### Embodiment 4

In this embodiment, a semiconductor device 8000 of one embodiment of the present invention will be described. The semiconductor device 8000 can function as a memory device.

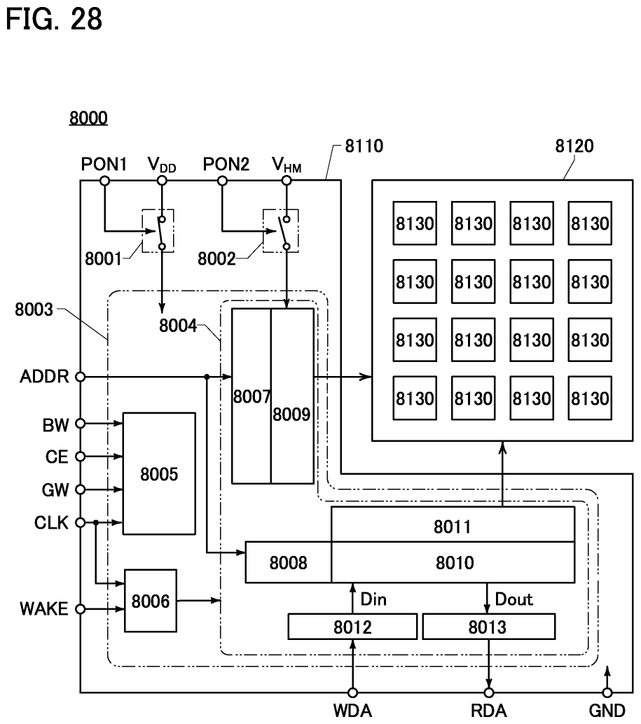

FIG. 28 is a block diagram of a structure example of the semiconductor device 8000. The semiconductor device 8000 in FIG. 28 includes a driver circuit 8110 and a memory array 8120. The memory array 8120 includes at least one memory cell 8130. FIG. 28 shows an example in which the memory array 8120 includes a plurality of memory cells 8130 arranged in a matrix.

As the memory cell 8130, the memory cell 10 described in Embodiment 1 and Embodiment 2 can be used. As part of the memory cell 8130 and part of the driver circuit 8110, the semiconductor device including the memory cell 10 described in Embodiment 1 and Embodiment 2 can be used.

The driver circuit 8110 includes a power switch (PSW) 8001, a PSW 8002, and a peripheral circuit 8003. The peripheral circuit 8003 includes a peripheral circuit 8004, a control circuit 8005, and a voltage generator circuit 8006.

In the semiconductor device, the circuits, signals, and voltages can be appropriately selected as needed. Another circuit or another signal may be added. Signals BW, CE, GW, CLK, WAKE, ADDR, WDA, PON1, and PON2 are signals input from the outside, and a signal RDA is a signal output to the outside. The signal CLK is a clock signal.

The signals BW, CE, and GW are control signals. The signal CE is a chip enable signal. The signal GW is a global write enable signal. The signal BW is a byte write enable signal. The signal ADDR is an address signal. The signal WDA is a write data signal, and the signal RDA is a read data signal. The signals PON1 and PON2 are power gating control signals. Note that the signals PON1 and PON2 may be generated in the control circuit 8005.

The control circuit 8005 is a logic circuit having a function of controlling the overall operation of the semiconductor device 8000. For example, the control circuit 8005 performs logical operation on the signals CE, GW, and BW to determine the operating mode (e.g., write operation or read operation) of the semiconductor device 8000. The control circuit 8005 generates a control signal for the peripheral circuit 8004 so that the operating mode is executed.

The voltage generator circuit 8006 has a function of generating negative voltage. The signal WAKE has a function of controlling the input of the signal CLK to the voltage generator circuit 8006. For example, when an H-level signal is applied as the signal WAKE, the signal CLK is input to the voltage generator circuit 8006, and the voltage generator circuit 8006 generates negative voltage.

The peripheral circuit 8004 is a circuit for writing and reading data to/from the memory cell 8130. The peripheral circuit 8004 includes a row decoder 8007, a column decoder 8008, a row driver 8009, a column driver 8010, a sense amplifier 8011, an input circuit 8012, and an output circuit 8013.

The row decoder 8007 and the column decoder 8008 have a function of decoding the signal ADDR. The row decoder 8007 is a circuit for specifying a row to be accessed. The column decoder 8008 is a circuit for specifying a column to be accessed. The row driver 8009 has a function of selecting the row specified by the row decoder 8007. The column driver 8010 has a function of writing data to the memory cell 8130, reading data from the memory cell 8130, and holding the read data, for example.

The input circuit 8012 has a function of holding the signal WDA. Data held in the input circuit 8012 is output to the column driver 8010. Data output from the input circuit 8012 is data (Din) written to the memory cell 8130. Data (Dout) read from the memory cell 8130 by the column driver 8010 is output to the output circuit 8013. The output circuit 8013 has a function of holding Dout. Moreover, the output circuit 8013 has a function of outputting Dout to the outside of the semiconductor device 8000. The data output from the output circuit 8013 is the signal RDA.

The PSW 8001 has a function of controlling the supply of V_{DD} to the peripheral circuit 8003. The PSW 8002 has a function of controlling the supply of V_{HM} to the row driver 8009. Here, in the semiconductor device 8000, a high power supply potential is V_{DD} and a low power supply potential is GND (ground potential). In addition, V_{HM} is a high power supply potential used for setting a word line to high level, and is higher than V_{DD}. The on/off state of the PSW 8001 is controlled by the signal PON1, and the on/off state of the PSW 8002 is controlled by the signal PON2. The number of power domains to which V_{DD} is supplied is one in the peripheral circuit 8003 in FIG. 28 but can be more than one. In that case, a power switch is provided for each power domain.

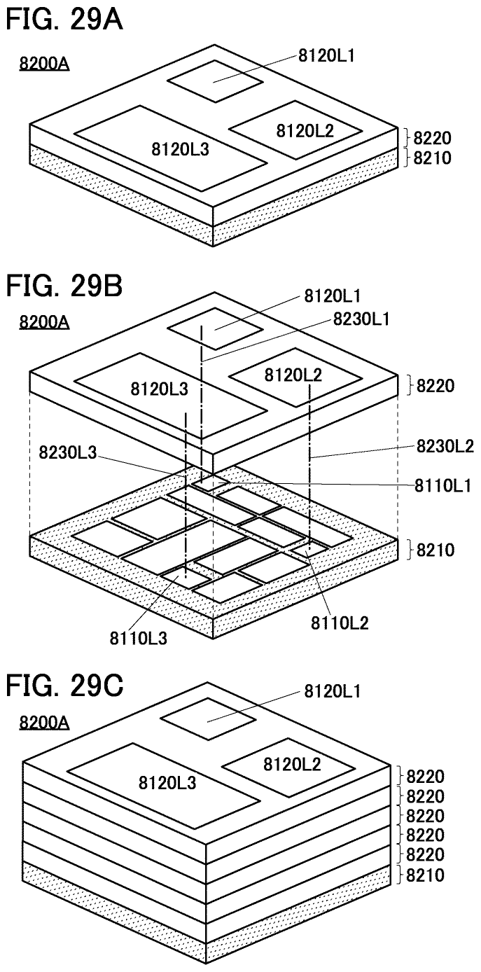

FIGS. 29A and 29C are perspective views of a semiconductor device 8200A. The semiconductor device 8200A includes a layer 8220 provided with memory arrays over an arithmetic device 8210. A memory array 8120L1, a memory array 8120L2, and a memory array 8120L3 are provided in the layer 8220. The arithmetic device 8210 and each of the memory arrays overlap with each other. For easy understanding of the structure of the semiconductor device 8200A, the arithmetic device 8210 and the layer 8220 are separately shown in FIG. 29B. As the arithmetic device 8210, a CPU, a GPU, or the like can be used, for example.

Overlapping the arithmetic device 8210 and the layer 8220 including the memory arrays can shorten the connection distance therebetween. Accordingly, the communication speed therebetween can be increased. Moreover, a short connection distance leads to lower power consumption.

As a method for stacking the layer 8220 including the memory arrays and the arithmetic device 8210, either of the following methods may be employed: a method in which the layer 8220 including the memory arrays is stacked directly on the arithmetic device 8210, which is also referred to as monolithic stacking, and a method in which the arithmetic device 8210 and the layer 8220 are formed over two different substrates, the substrates are bonded to each other, and the arithmetic device 8210 and the layer 8220 are connected to each other with a through via or by a technique for bonding conductive films (e.g., Cu-Cu bonding). The former method does not require consideration of misalignment in bonding; thus, not only the chip size but also the manufacturing cost can be reduced.

Here, it is possible that the arithmetic device 8210 does not include the cache and the memory arrays 8120L1, 8120L2, and 8120L3 provided in the layer 8220 are each used as a cache. In this case, for example, the memory array 8120L1, the memory array 8120L2, and the memory array 8120L3 can be used as an L1 cache (also referred to as a level 1 cache), an L2 cache (also referred to as a level 2 cache), and an L3 cache (also referred to as a level 3 cache), respectively. Among the three memory arrays, the memory array 8120L3 has the highest capacity and the lowest access frequency. The memory array 8120L1 has the lowest capacity and the highest access frequency.

Note that in the case where the cache provided in the arithmetic device 8210 is used as the L1 cache, the memory arrays provided in the layer 8220 can each be used as the lower-level cache or the main memory. The main memory has higher capacity and lower access frequency than the cache.

As shown in FIG. 29B, a driver circuit 8110L1, a driver circuit 8110L2, and a driver circuit 8110L3 are provided. The driver circuit 8110L1 is connected to the memory array 8120L1 through a connection electrode 8230L1. Similarly, the driver circuit 8110L2 is connected to the memory array 8120L2 through a connection electrode 8230L2, and the driver circuit 8110L3 is connected to the memory array 8120L3 through a connection electrode 8230L3.

Note that although the case where three memory arrays function as caches is described here, the number of memory cell arrays may be one, two, or four or more.

In the case where the memory array 8120L1 is used as a cache, the driver circuit 8110L1 may function as part of the cache interface or the driver circuit 8110L1 may be connected to the cache interface. Similarly, each of the driver circuits 8110L2 and 8110L3 may function as part of the cache interface or be connected thereto.

Although FIGS. 29A and 29B show an example in which one layer 8220 provided with the memory arrays is provided over the arithmetic device 8210, two or more layers 8220 provided with the memory arrays may be provided as shown in FIG. 29C.

At least part of this embodiment can be implemented as appropriate in combination with any of the other embodiments or examples described in this specification.

### Embodiment 5

In this embodiment, application examples of the semiconductor device of one embodiment of the present invention will be described. The semiconductor device of one embodiment of the present invention can include a transistor having favorable electrical characteristics and a small occupation area; thus, the semiconductor device is suitable for, for example, an electronic component, an electronic device, a large computer, a device for space, and a data center.

### Electronic Component

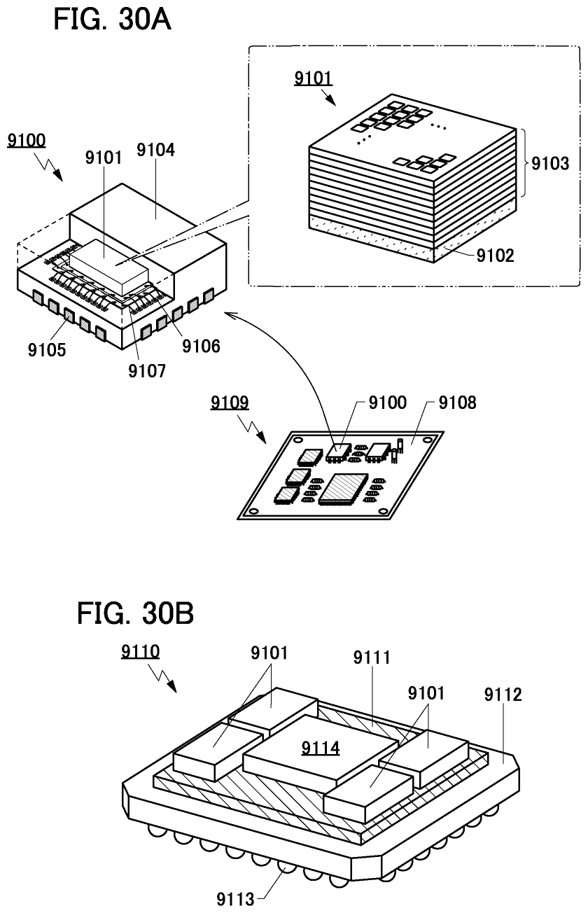

FIG. 30A is a perspective view of a substrate (a circuit board 9109) provided with an electronic component 9100. The electronic component 9100 in FIG. 30A includes a semiconductor device 9101 in a mold 9104. FIG. 30A omits some components to show the inside of the electronic component 9100. The electronic component 9100 includes a land 9105 outside the mold 9104. The land 9105 is electrically connected to an electrode pad 9106, and the electrode pad 9106 is electrically connected to the semiconductor device 9101 through a wire 9107. The electronic component 9100 is mounted on a printed circuit board 9108, for example. A plurality of such electronic components are combined and electrically connected to each other on the printed circuit board 9108, which forms the circuit board 9109.

The semiconductor device 9101 includes a driver circuit layer 9102 and a memory layer 9103. The memory layer 9103 has a structure where a plurality of memory cell arrays are stacked. A stacked-layer structure of the driver circuit layer 9102 and the memory layer 9103 can be a monolithic stacked-layer structure. In the monolithic stacked-layer structure, layers can be connected to each other without using a through electrode technique such as a through silicon via (TSV) technique and a bonding technique such as Cu-to-Cu direct bonding. Monolithically stacking the driver circuit layer 9102 and the memory layer 9103 enables, for example, what is called an on-chip memory structure where a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is used, which means that the number of connection pins can be increased. The increase in the number of connection pins enables parallel operations, which can improve the bandwidth of the memory (also referred to as a memory bandwidth).

It is preferable that the plurality of memory cell arrays included in the memory layer 9103 be formed with OS transistors and be monolithically stacked. Monolithically stacking the plurality of memory cell arrays can improve one or both of a memory bandwidth and a memory access latency. Note that the bandwidth refers to the data transfer volume per unit time, and the access latency refers to a period of time from data access to the start of data transmission. Note that in the case where the memory layer 9103 is formed with Si transistors, the monolithic stacked-layer structure is difficult to form compared with the case where the memory layer 9103 is formed with OS transistors. Therefore, an OS transistor is superior to a Si transistor in the monolithic stacked-layer structure.

The semiconductor device 9101 may be called a die. Note that in this specification and the like, a die refers to a chip obtained by, for example, forming a circuit pattern on a disc-like substrate (also referred to as a wafer) or the like and cutting the substrate with the pattern into dices in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

FIG. 30B is a perspective view of an electronic component 9110. The electronic component 9110 is an example of a system in package (SiP) or a multi-chip module (MCM). In the electronic component 9110, an interposer 9111 is provided over a package substrate 9112 (printed circuit board), and a semiconductor device 9114 and a plurality of semiconductor devices 9101 are provided over the interposer 9111.

The electronic component 9110 using the semiconductor device 9101 as a high bandwidth memory (HBM) is shown as an example. The semiconductor device 9114 can be used for an integrated circuit such as a CPU, a GPU, or a field programmable gate array (FPGA).

As the package substrate 9112, a ceramic substrate, a plastic substrate, or a glass epoxy substrate can be used, for example. As the interposer 9111, a silicon interposer, a resin interposer, or a glass interposer can be used, for example.

The interposer 9111 includes a plurality of wirings and has a function of connecting a plurality of integrated circuits with different terminal pitches. The plurality of wirings are provided in a single layer or multiple layers. In addition, the interposer 9111 has a function of connecting an integrated circuit provided on the interposer 9111 to an electrode provided on the package substrate 9112. Accordingly, the interposer is referred to as a “redistribution substrate” or an “intermediate substrate” in some cases. Furthermore, a through electrode is provided in the interposer 9111 and the through electrode is used to connect an integrated circuit and the package substrate 9112 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are connected with use of a silicon interposer, a TSV, and the like, a space for a width of the terminal pitch and the like is needed. Accordingly, in the case where the size of the electronic component 9110 is reduced, the width of the terminal pitch becomes an issue, which sometimes makes it difficult to provide a large number of wirings for obtaining a wide memory bandwidth. For this reason, the above-described monolithic stacked-layer structure with use of OS transistors is suitable. A composite structure combining memory cell arrays stacked using a TSV and monolithically stacked memory cell arrays may be employed.

In addition, a heat sink (a radiator plate) may be provided to overlap with the electronic component 9110. In the case of providing a heat sink, the heights of integrated circuits provided on the interposer 9111 are preferably equal to each other. For example, in the electronic component 9110 described in this embodiment, the heights of the semiconductor devices 9101 and 9114 are preferably equal to each other.

To mount the electronic component 9110 on another substrate, an electrode 9113 may be provided on a bottom portion of the package substrate 9112. FIG. 30B shows an example where the electrode 9113 is formed of a solder ball. Solder balls are provided in a matrix on the bottom portion of the package substrate 9112, so that ball grid array (BGA) mounting can be achieved. Alternatively, the electrode 9113 may be formed of a conductive pin. When conductive pins are provided in a matrix on the bottom portion of the package substrate 9112, pin grid array (PGA) mounting can be achieved.

The electronic component 9110 can be mounted on another substrate by various mounting methods other than BGA and PGA. Examples of a mounting method include staggered pin grid array (SPGA), land grid array (LGA), quad flat package (QFP), quad flat J-leaded package (QFJ), and quad flat non-leaded package (QFN).

### Large Computer

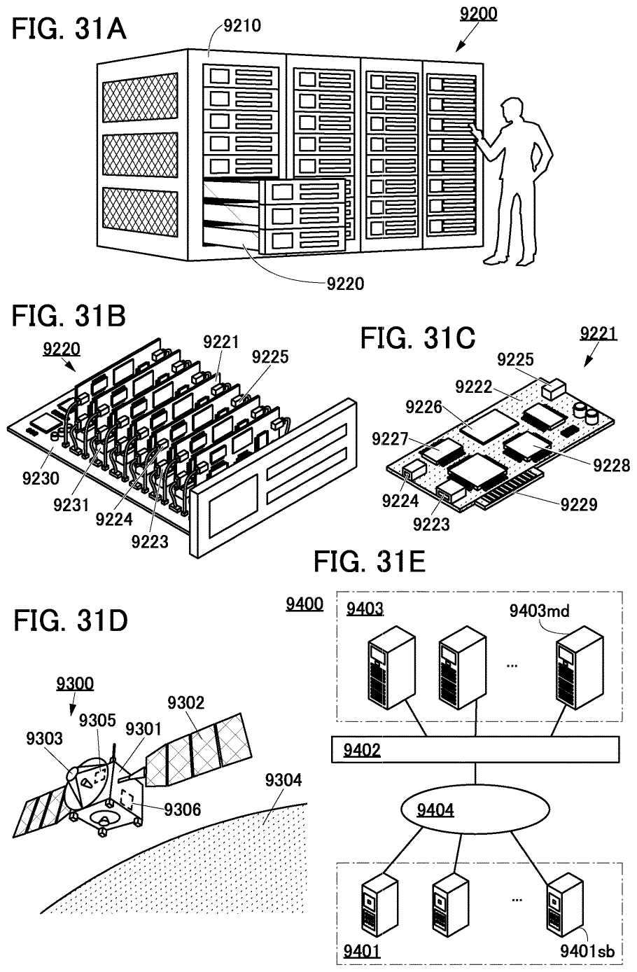

FIG. 31A is a perspective view of a large computer 9200. In the large computer 9200 in FIG. 31A, a plurality of rack mount computers 9220 are stored in a rack 9210. Note that the large computer 9200 may be referred to as a supercomputer.

The computer 9220 can have a structure shown in a perspective view in FIG. 31B, for example. In FIG. 31B, the computer 9220 includes a motherboard 9230, and the motherboard 9230 includes a plurality of slots 9231 and a plurality of connection terminals. A PC card 9221 is inserted in the slot 9231. In addition, the PC card 9221 includes a connection terminal 9223, a connection terminal 9224, and a connection terminal 9225, each of which is connected to the motherboard 9230.

The PC card 9221 shown in FIG. 31C is an example of a processing board provided with a CPU, a GPU, a memory device, and the like. The PC card 9221 includes a board 9222. The board 9222 includes the connection terminal 9223, the connection terminal 9224, the connection terminal 9225, a semiconductor device 9226, a semiconductor device 9227, a semiconductor device 9228, and a connection terminal 9229. Note that FIG. 31C also shows semiconductor devices other than the semiconductor devices 9226, 9227, and 9228, and the following description of the semiconductor devices 9226, 9227, and 9228 can be referred to for these semiconductor devices.

The connection terminal 9229 has a shape with which the connection terminal 9229 can be inserted in the slot 9231 of the motherboard 9230, and the connection terminal 9229 functions as an interface for connecting the PC card 9221 and the motherboard 9230.

The semiconductor device 9226 includes a terminal (not shown) for inputting and outputting signals, and when the terminal is inserted in a socket (not shown) of the board 9222, the semiconductor device 9226 and the board 9222 can be connected to each other.

Examples of the semiconductor device 9227 include an FPGA, a GPU, and a CPU. As the semiconductor device 9227, the electronic component 9110 can be used, for example.

An example of the semiconductor device 9228 is a memory device or the like. As the semiconductor device 9228, the electronic component 9110 can be used, for example.

The large computer 9200 can also function as a parallel computer. When the large computer 9200 is used as a parallel computer, large-scale computation necessary for artificial intelligence learning and inference can be performed, for example.

### Device for Space

The semiconductor device of one embodiment of the present invention can be suitably used as a device for space.

The semiconductor device of one embodiment of the present invention includes an OS transistor. A change in electrical characteristics due to exposure to radiation is smaller in an OS transistor than in a Si transistor. That is, the OS transistor is highly resistant to radiation and thus has high reliability and can be suitably used in an environment where radiation can enter. For example, the OS transistor can be suitably used in outer space. Specifically, the OS transistor can be used as a transistor in a semiconductor device provided in a space shuttle, an artificial satellite, or a space probe. Note that although outer space refers to, for example, space at an altitude greater than or equal to 100 km, outer space described in this specification can include one or more of thermosphere, mesosphere, and stratosphere.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

FIG. 31D shows an artificial satellite 9300 as an example of a device for space. The artificial satellite 9300 includes a body 9301, a solar panel 9302, an antenna 9303, a secondary battery 9305, and a control device 9306. In FIG. 31D, a planet 9304 in outer space is shown as an example.

Although not shown in FIG. 31D, a battery management system (also referred to as BMS) or a battery control circuit may be provided in the secondary battery 9305. The battery management system or the battery control circuit preferably uses the OS transistor, in which case low power consumption and high reliability are achieved even in outer space.

The control device 9306 has a function of controlling the artificial satellite 9300. The control device 9306 is formed with one or more selected from a CPU, a GPU, and a memory device, for example. Note that the semiconductor device including the OS transistor of one embodiment of the present invention is suitably used for the control device 9306.

Although the artificial satellite is described as an example of a device for space in this embodiment, one embodiment of the present invention is not limited to this example. The semiconductor device of one embodiment of the present invention can be suitably used for a device for space such as a spacecraft, a space capsule, or a space probe, for example.

As described above, an OS transistor has excellent effects of achieving a wide memory bandwidth and high radiation tolerance as compared with a Si transistor.

### Data Center

The semiconductor device of one embodiment of the present invention can be suitably used for, for example, a storage system in a data center or the like. Long-term management of data, such as guarantee of data immutability, is required for the data center. The long-term management of data needs setting a storage and a server for holding a huge amount of data, stable power supply for holding data, cooling equipment for holding data, an increase in building size, and the like.

With use of the semiconductor device of one embodiment of the present invention for a storage system in a data center, power used for holding data can be reduced and a semiconductor device for holding data can be downsized. Accordingly, downsizing of the storage system and the power supply for holding data, downscaling of the cooling equipment, and the like can be achieved. Therefore, a space of the data center can be reduced.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be increased.

FIG. 31E shows a storage system that can be used in a data center. A storage system 9400 in FIG. 31E includes a plurality of servers 9401sb as a host 9401. The storage system 9400 includes a plurality of memory devices 9403md as a storage 9403. In the shown example, the host 9401 and the storage 9403 are connected to each other through a storage area network 9404 and a storage control circuit 9402.

The host 9401 corresponds to a computer that accesses data stored in the storage 9403. The host 9401 may be connected to another host 9401 through a network.

The data access speed, i.e., the time taken for storing and outputting data, of the storage 9403 is shortened by using a flash memory, but is still considerably longer than the data access speed of a DRAM that can be used as a cache memory in a storage. In the storage system, in order to solve the problem of low access speed of the storage 9403, a cache memory is normally provided in the storage to shorten the time taken for data storage and output.

The above-described cache memory is used in the storage control circuit 9402 and the storage 9403. The data transmitted between the host 9401 and the storage 9403 is stored in the cache memories in the storage control circuit 9402 and the storage 9403 and then output to the host 9401 or the storage 9403.

With a structure in which an OS transistor is used as a transistor for holding data in the cache memory to retain a potential based on data, the frequency of refreshing can be decreased, so that power consumption can be reduced. Furthermore, downscaling is possible by stacking memory cell arrays.

At least part of this embodiment can be implemented as appropriate in combination with any of the other embodiments or examples described in this specification.

This application is based on Japanese Patent Application Serial No. 2025-076827 filed with Japan Patent Office on May 2, 2025, the entire contents of which are hereby incorporated by reference.

What is claimed is:

1. A semiconductor device comprising:
a memory cell comprising a first transistor, a second transistor, and a third transistor,
wherein a gate of the first transistor is electrically connected to a first wiring,
wherein one of a source and a drain of the first transistor is electrically connected to a second wiring,
wherein the other of the source and the drain of the first transistor is electrically connected to a gate of the second transistor and a gate of the third transistor,
wherein one of a source and a drain of the second transistor is electrically connected to a fifth wiring,
wherein the other of the source and the drain of the second transistor is electrically connected to a third wiring,
wherein one of a source and a drain of the third transistor is electrically connected to a fourth wiring,
wherein the other of the source and the drain of the third transistor is electrically connected to the fifth wiring,
wherein the first wiring is configured to be supplied with a first signal,
wherein the second wiring is configured to be supplied with a second signal,
wherein, in a first period, each of the third wiring, the fourth wiring, and the fifth wiring is configured to be supplied with a first potential, and
wherein, in a second period, the third wiring is configured to be supplied with a second potential higher than the first potential, the fourth wiring is configured to be supplied with a third potential lower than the first potential, and the fifth wiring is configured to output one of the second potential and the third potential.

2. The semiconductor device according to claim 1, further comprising:
a precharge circuit and a sense amplifier circuit,
wherein the fifth wiring is electrically connected to an output terminal of the precharge circuit and a first input terminal of the sense amplifier circuit.

3. The semiconductor device according to claim 2,
wherein a second input terminal of the sense amplifier circuit is electrically connected to the fifth wiring of an adjacent memory cell of the memory cell.

4. The semiconductor device according to claim 1,
wherein a channel formation region of the first transistor comprises indium, and
wherein a channel formation region of each of the second transistor and the third transistor comprises silicon.

5. A semiconductor device comprising:
a memory cell comprising a first transistor, a second transistor, a third transistor, and a fourth transistor,
wherein a gate of the first transistor is electrically connected to a first wiring,
wherein one of a source and a drain of the first transistor is electrically connected to a second wiring,
wherein the other of the source and the drain of the first transistor is electrically connected to a gate of the second transistor and a gate of the third transistor,
wherein one of a source and a drain of the third transistor is electrically connected to a fourth wiring,
wherein one of a source and a drain of the second transistor is electrically connected to the other of the source and the drain of the third transistor and one of a source and a drain of the fourth transistor,
wherein the other of the source and the drain of the second transistor is electrically connected to a third wiring,
wherein the other of the source and the drain of the fourth transistor is electrically connected to a fifth wiring, and
wherein a gate of the fourth transistor is electrically connected to a sixth wiring.

6. The semiconductor device according to claim 5, further comprising:
a precharge circuit and a sense amplifier circuit,
wherein the fifth wiring is electrically connected to an output terminal of the precharge circuit and a first input terminal of the sense amplifier circuit.

7. The semiconductor device according to claim 6,
wherein a second input terminal of the sense amplifier circuit is electrically connected to the fifth wiring of an adjacent memory cell of the memory cell.

8. The semiconductor device according to claim 5,
wherein a channel formation region of the first transistor comprises indium, and
wherein a channel formation region of each of the second transistor and the third transistor comprises silicon.

9. The semiconductor device according to claim 5,
wherein the first wiring is configured to be supplied with a first signal,
wherein the second wiring is configured to be supplied with a second signal,
wherein, in a first period, each of the third wiring, the fourth wiring, and the fifth wiring is configured to be supplied with a first potential, and
wherein, in a second period, electrical continuity is established between the source and the drain of the fourth transistor, the third wiring is configured to be supplied with a second potential higher than the first potential, the fourth wiring is configured to be supplied with a third potential lower than the first potential, and the fifth wiring is configured to output one of the second potential and the third potential.

10. The semiconductor device according to claim 9, further comprising:
a precharge circuit and a sense amplifier circuit,
wherein the fifth wiring is electrically connected to an output terminal of the precharge circuit and a first input terminal of the sense amplifier circuit.

11. The semiconductor device according to claim 10,
wherein a second input terminal of the sense amplifier circuit is electrically connected to the fifth wiring of an adjacent memory cell of the memory cell.

12. The semiconductor device according to claim 9,
wherein a channel formation region of the first transistor comprises indium, and
wherein a channel formation region of each of the second transistor and the third transistor comprises silicon.

13. A semiconductor device comprising:
a memory cell comprising a first transistor, a second transistor, and a third transistor,
wherein the first transistor is positioned above the second transistor and the third transistor,
wherein the first transistor comprises a first semiconductor, a first insulator, a second insulator, a first conductor, a second conductor, and a third conductor,
wherein the second insulator is positioned over the second conductor;
wherein the third conductor is positioned over the second insulator,
wherein the second insulator comprises an opening portion reaching the second conductor,
wherein the first semiconductor comprises a region in contact with the third conductor and a region positioned in the opening portion and in contact with the second conductor,
wherein the first insulator is positioned between the first conductor and the first semiconductor,
wherein the second transistor comprises a second semiconductor, a third insulator, a fourth conductor, a fifth conductor, and a sixth conductor,
wherein the second semiconductor comprises a region in contact with the fifth conductor and a region in contact with the sixth conductor,
wherein the fourth conductor is provided to surround a top surface, a bottom surface, and a pair of opposite side surfaces of the second semiconductor,
wherein the third insulator comprises a region positioned between the fourth conductor and the second semiconductor,
wherein the third transistor comprises a third semiconductor, a fourth insulator, a seventh conductor, an eighth conductor, and a ninth conductor,
wherein the third semiconductor comprises a region in contact with the eighth conductor and a region in contact with the ninth conductor,
wherein the seventh conductor is provided to surround a top surface, a bottom surface, and a pair of opposite side surfaces of the third semiconductor,
wherein the fourth insulator comprises a region positioned between the seventh conductor and the third semiconductor,
wherein the first semiconductor comprises indium,
wherein the second semiconductor and the third semiconductor comprise silicon or silicon germanium,
wherein the second conductor is electrically connected to the fourth conductor and the seventh conductor, and
wherein the sixth conductor is electrically connected to the ninth conductor.

14. The semiconductor device according to claim 13,
wherein at least one of the fifth conductor, the sixth conductor, the eighth conductor, and the ninth conductor comprises silicide.

15. The semiconductor device according to claim 13,
wherein the second semiconductor and the third semiconductor overlap with each other in a plan view.

16. The semiconductor device according to claim 13,
wherein the first semiconductor comprises a region in contact with a side surface of the second insulator in the opening portion, and
wherein the first insulator and the first conductor comprise a region positioned in the opening portion.

17. The semiconductor device according to claim 13,
wherein the first conductor comprises a region in contact with a top surface of the second insulator and positioned over the second conductor and under the third conductor, and
wherein the first insulator comprises a region in contact with a side surface of the second insulator in the opening portion.
